(19) United States
(12) Patent Application Publication
(10) Pub. No.: US 2026/0353783 A1
(43) Pub. Date: Nov. 5, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Yu-Hung CHENG, Tainan City (TW); Kuan-Liang LIU, Tainan (TW); Liang-Yu SU, Yunlin County (TW); Ching I LI, Tainan (TW)

(21) Appl. No.: 19/197,628

(22) Filed: May 2, 2025

(51) Int. Cl. H10D 84/83; H10D 30/01; H10D 30/65; H10P 14/20; H10P 50/00; H10W 10/00; H10W 10/40

(52) U.S. Cl. CPC H10D 84/835; H10D 30/0281; H10D 30/655; H10P 14/3411; H10P 50/692; H10W 10/041; H10W 10/40

(57) ABSTRACT

An isolation structure for a high-voltage region of a semiconductor device may be manufactured using self-aligned doping techniques to reduce the time, cost, and/or complexity of manufacturing the isolation structure. As described herein, a trench may be formed in and/or through a semiconductor layer of the semiconductor device. One or more self-aligned epitaxy operations may be performed to epitaxially grow one or more semiconductor liners on the sidewalls of the trench. The trench may then be filled in with material of an insert. The semiconductor liner(s) and the insert correspond to the isolation structure, and the isolation structure laterally surrounds the high-voltage region of the semiconductor device. The use of the self-aligned epitaxy technique described herein enables the formation of the semiconductor liner(s) to be highly controlled, which provides for a high amount of control over film thickness, contamination, and defect rate for the semiconductor liner(s).

### BACKGROUND

A high-voltage transistor is a type of metal oxide semiconductor (MOS) transistor that may be configured to operate at a higher drain voltage relative to a low voltage transistor. Low voltage transistors may be used in applications such as logic circuits (e.g., processors), memory (e.g., static random access memory (SRAM)), and/or input/output (I/O) circuits, among other examples. High-voltage transistors may be used in applications such as integrated circuit (IC) drivers, power ICs, image sensors, power management, display driver ICs (DDICs), bipolar complementary metal oxide semiconductor (CMOS) diffused metal oxide semiconductor (DMOS) ICs (BCD ICs), and/or image signal processing (ISP) ICs, among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrams of an example semiconductor device described herein.

FIGS. 2A-2O are diagrams of an example implementation of forming a high-voltage region in a semiconductor device described herein.

FIG. 3 illustrates an example implementation of an isolation structure described herein.

FIG. 4 illustrates an example implementation of a dopant composition of semiconductor liners of an isolation structure described herein.

FIG. 5 illustrates an example implementation of an isolation structure described herein.

FIG. 6 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

To operate at higher drain voltages, a high-voltage transistor may be manufactured to withstand a high breakdown voltage. Breakdown voltage is a voltage at or near which a transistor ceases to operate according to the intended operating principles of the transistor. In a high-voltage transistor, the breakdown voltage may be as high as 100 volts or greater.

Electrical isolation included in a semiconductor device for high-voltage transistors may also be required to withstand the high breakdown voltages of the high-voltage transistors. However, manufacturing electrical isolation structures to withstand the high breakdown voltages may involve complex and costly manufacturing processes that may increase the time, cost, and/or complexity of manufacturing the semiconductor device. Additionally and/or alternatively, these manufacturing processes may be prone to process variation, which may increase the likelihood of defect formation in the electrical isolation structures, which may inhibit the ability of the electrical isolation structures to withstand such high breakdown voltages.

In some implementations described herein, an isolation structure for a high-voltage region of a semiconductor device may be manufactured using self-aligned doping techniques to reduce the time, cost, and/or complexity of manufacturing the isolation structure. As described herein, a trench may be formed in and/or through a semiconductor layer of the semiconductor device. One or more self-aligned epitaxy operations may be performed to epitaxially grow one or more semiconductor liners on the sidewalls of the trench. The trench may then be filled in with material of an insert. The semiconductor liner(s) and the insert correspond to the isolation structure, and the isolation structure laterally surrounds the high-voltage region of the semiconductor device.

The use of the self-aligned epitaxy technique described herein may be more cost effective and less complex than other techniques such as two-part ion implantation. Moreover, the use of the self-aligned epitaxy technique described herein enables the formation of the semiconductor liner(s) to be highly controlled, which provides for a high amount of control over film thickness, contamination, and defect rate for the semiconductor liner(s). This enables a low defect rate to be achieved for the isolation liner, and enables the isolation liner to better withstand high breakdown voltages than if the isolation structure were formed using other process techniques.

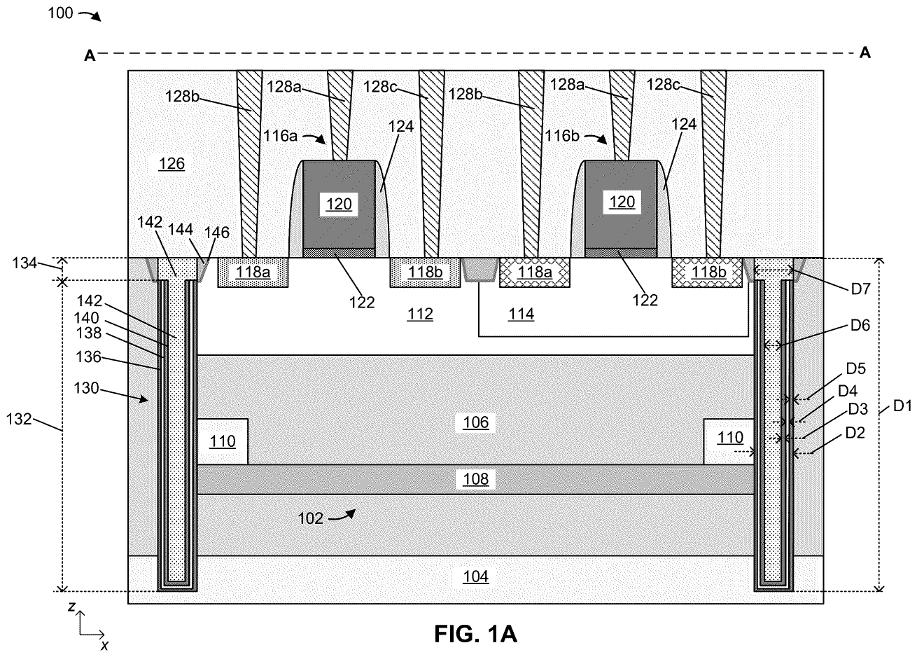

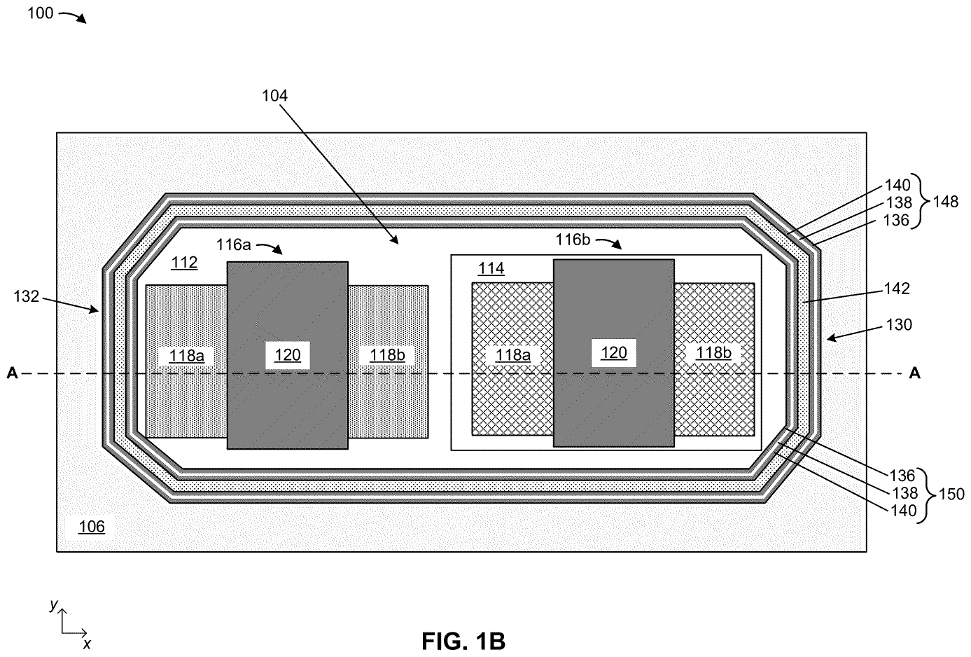

FIGS. 1A and 1B are diagrams of an example semiconductor device 100 described herein. The semiconductor device 100 includes a system on chip (SoC) device, a logic device such as a central processing unit (CPU) or a graphics processing unit (GPU), a memory device (e.g., a high bandwidth memory (HBM) device), a panel driver device, an integrated circuit (IC) driver, a radio frequency (RF) power amplifier, a display driver IC (DDIC), and/or another type of semiconductor device that includes at least one high-voltage region 102. The high-voltage region 102 is a region of the semiconductor device 100 in which one or more high-voltage devices are included. The high-voltage region 102 may be electrically isolated from other regions of the semiconductor device 100, which enables the semiconductor device 100 to include low-voltage devices, medium-voltage devices, and/or another type of integrated circuit devices.

FIG. 1A illustrates a cross-section view of the high-voltage region 102 along a line A-A, and FIG. 1B illustrates a top view of the high-voltage region 102, including the location of the cross-section of FIG. 1A.

As shown in FIG. 1A, the semiconductor device 100 may include a substrate layer 104. The substrate layer 104 may extend in an x-direction and/or in a y-direction in the semiconductor device 100. The substrate layer 104 may include at least a portion of a substrate on which the semiconductor device 100 was formed. For example, the substrate layer 104 may correspond to a portion of a semiconductor wafer on which the semiconductor device 100 was formed. The substrate layer 104 may include a semiconductor layer such as a silicon (Si) layer, a layer formed of a material including silicon, a III-V compound semiconductor material layer such as gallium arsenide (GaAs), and/or another type of semiconductor layer. In some implementations, the substrate layer 104 is a portion of a semiconductor layer of a silicon on insulator (SOI) substrate.

In some implementations, the substrate layer 104 is a bottom portion of the substrate, and additional semiconductor layers of the substrate are formed on the bottom substrate layer 104. For example, a semiconductor layer 106 may be included above the substrate layer 104 of the semiconductor device 100. A buried doped semiconductor layer 108 may be included in the semiconductor layer 106.

The semiconductor layer 106 may be a layer that is epitaxially grown above the substrate layer 104. In some implementations, the semiconductor layer 106 is a doped semiconductor layer such as silicon (Si) that is doped with one or more types of dopants. For example, the semiconductor layer 106 may include one or more p-type dopants such as boron (B). As another example, the semiconductor layer may include one or more n-type dopants such as arsenic (As) and/or phosphorus (P), among other examples. In some implementations, the semiconductor layer 106 includes p-type dopants and n-type dopants.

The buried doped semiconductor layer 108 may also include one or more types of dopants. In some implementations, the buried doped semiconductor layer 108 includes a different dopant type of than the semiconductor layer 106. For example, the semiconductor layer 106 may include a layer of epitaxially-grown silicon (Si) that is doped with one or more p-type dopants, and the buried doped semiconductor layer 108 may include a region of the semiconductor layer 106 that is doped with one or more n-type dopants. Alternatively, the buried doped semiconductor layer 108 may be epitaxially grown from semiconductor material that includes the n-type dopant(s).

The buried doped semiconductor layer 108 may provide bottom electrical isolation for the high-voltage region 102. The buried doped semiconductor layer 108 may reduce and/or minimize current leakage through the semiconductor layer 106 and into the substrate layer 104. In some implementations, buried semiconductor layer extension regions 110 are included around the perimeter of the buried doped semiconductor layer 108. The buried semiconductor layer extension regions 110 may be doped with the same dopant type as the buried doped semiconductor layer 108, and may include approximately a same dopant concentration as the buried doped semiconductor layer 108, or may include a different dopant concentration than the buried doped semiconductor layer 108. For example, the dopant concentration in the buried semiconductor layer extension regions 110 may be greater than the dopant concentration in the buried doped semiconductor layer 108.

As further shown in FIG. 1A, a first type doped well region 112 may be included in a portion of the semiconductor layer 106 in the high-voltage region 102, and a second type doped well region 114 may be included in a portion of the semiconductor layer 106 in the high-voltage region 102. In some implementations, the first type doped well region 112 includes a p-type well region, which may include a portion of the semiconductor layer 106 that is doped with one or more p-type dopants. In some implementations, the second type doped well region 114 includes an n-type well region, which may include a portion of the semiconductor layer 106 that is doped with one or more n-type dopants.

An integrated circuit device 116a may be included in and/or on the first type doped well region 112 in the high-voltage region 102, and may include an n-type high-voltage transistor. An integrated circuit device 116b may be included in and/or on the second type doped well region 114 in the high-voltage region 102, and may include a p-type high-voltage transistor.

A “high-voltage transistor” refers to a transistor that is configured to operate at higher operating voltages (e.g., higher gate voltages, higher source/drain voltages) than low voltage transistors. As an example, a high-voltage transistor may be configured to operate in a drain voltage range of approximately 9 volts to approximately 36 volts, whereas a low-voltage transistor may be configured to operate in a drain voltage range of approximately 0 volts to approximately 1.8 volts. However, other values for these ranges are within the scope of the present disclosure. For example, the integrated circuit devices 116a, 116b may be configured to operate at drain voltages of approximately 50 volts or greater.

The integrated circuit devices 116a and 116b may each include a high-voltage transistor structure, such as a high-voltage planar transistor structure, a high-voltage fin field effect transistor (finFET) structure, a high-voltage nanostructure transistor structure (e.g., a gate all around (GAA) transistor structure, a nanosheet transistor structure, a nanowire transistor structure, a multi-bridge channel transistor structure, a nanoribbon transistor structure), and/or another type of transistor structure.

In some implementations, integrated circuit devices 116a and/or 116b may include a laterally diffused (or laterally double diffused) metal-oxide semiconductor (LDMOS) transistor that has a drift region in which charge carriers are laterally diffused in the semiconductor layer 106 to facilitate lateral distribution of an electric field between a gate structure and a source/drain region of the high-voltage transistor. The lateral diffusion of charge carriers in the drift region enables the high-voltage transistor to withstand higher gate and source/drain voltages (e.g., by increasing the breakdown voltage of the high-voltage transistor) than low voltage transistors.

In some implementations, a high-voltage transistor may include a vertically diffused (or vertically double diffused) metal-oxide semiconductor (vertical DMOS or VDMOS) transistor that has a drift region in which charge carriers are vertically diffused in the semiconductor layer 106 to facilitate vertical distribution of an electric field between a gate structure and a source/drain region of the high-voltage transistor. The vertical diffusion of charge carriers in the drift region enables the high-voltage transistor to withstand higher gate and source/drain voltages while still achieving a smaller lateral footprint than an LDMOS transistor.

The integrated circuit devices 116a and 116b may each include a plurality of source/drain regions 118a and 118b located on laterally opposing sides of a gate structure 120. “Source/drain region” may refer to a source region, a drain region, or a combination of a source and drain region, depending on the context. In some implementations, the integrated circuit devices 116a and 116b share a source/drain region such that the integrated circuit devices 116a and 116b are electrically coupled through the shared source/drain region.

The source/drain regions 118a and 118b may each include one or more doped regions or layers of doped material. In some implementations, the source/drain regions 118a and 118b of the integrated circuit device 116a may include the same dopant type, and the source/drain regions 118a and 118b of the integrated circuit device 116b may include the same dopant type. For example, the source/drain regions 118a and 118b of the integrated circuit device 116a may include p-type dopant types, and the source/drain regions 118a and 118b of the integrated circuit device 116b may include n-type dopants. In some implementations, the source/drain regions 118a and 118b of the integrated circuit device 116a include different dopant types, and the source/drain regions 118a and 118b of the integrated circuit device 116b include different dopant types.

A portion of the first type doped well region 112 under the gate structure 120 of the integrated circuit device 116a between the source/drain regions 118a and 118b may correspond to a channel region of the of the integrated circuit device 116a. A portion of the second type doped well region 114 under the gate structure 120 of the integrated circuit device 116b between the source/drain regions 118a and 118b may correspond to a channel region of the of the integrated circuit device 116b. In some implementations, the gate structures 120 include polysilicon gates. In some implementations, the gate structures 120 include metal gates and includes one or more metal materials such as tungsten (W), titanium (Ti), titanium aluminum (TiAl), and/or other suitable metal materials.

A gate dielectric layer 122 may be located between the gate structure 120 of the integrated circuit device 116a and the first type doped well region 112, and gate dielectric layer 122 may be located between the gate structure 120 of the integrated circuit device 116b and the second type doped well region 114.

The gate dielectric layer 122 of the integrated circuit device 116a enables an electric field to be selectively formed in the first type doped well region 112 to control the electrical conductivity of the integrated circuit device 116a between the source/drain regions 118a and 118b. An electrical bias may be selectively applied to the gate structure 120 of the integrated circuit device 116a to selectively control the electric field, and therefore the electrical conductivity of the channel. In this way, charge carriers may selectively flow between the source/drain regions 118a and 118b based on the electrical conductivity of the channel of the integrated circuit device 116a.

The gate dielectric layer 122 of the integrated circuit device 116b enables an electric field to be selectively formed in the second type doped well region 114 to control the electrical conductivity of the integrated circuit device 116b between the source/drain regions 118a and 118b. An electrical bias may be selectively applied to the gate structure 120 of the integrated circuit device 116b to selectively control the electric field, and therefore the electrical conductivity of the channel. In this way, charge carriers may selectively flow between the source/drain regions 118a and 118b based on the electrical conductivity of the channel of the integrated circuit device 116b.

In some implementations, the gate dielectric layers 122 may each include a low dielectric constant (low-k) dielectric material such as a silicon oxide (SiOₓ such as SiO₂).

Additionally and/or alternatively, the gate dielectric layers 122 may each include a high dielectric constant (high-k) dielectric material (e.g., a dielectric material having a dielectric constant that is greater than approximately 3.9) such as a silicon nitride (SiₓN_{y} such as Si₃N₄), a hafnium oxide (HfOₓ such as HfO₂), and/or aluminum oxide (AlₓO_{y} such as Al₂O₃), among other examples.

One or more sidewall spacers 124 may be included over and/or on sidewalls of the gate structures 120 of the integrated circuit devices 116a, 116b. The sidewall spacers 124 may include a silicon oxycarbide (SiOC), a nitrogen free SiOC, or another suitable dielectric material. The sidewall spacers 124 may have a curved or rounded outer surface as a result of a directional (e.g., vertical) etch technique that is used to form the sidewall spacers 124.

As further shown in FIG. 1A, a dielectric layer 126 may be included above the semiconductor layer 106 and over the integrated circuit devices 116a and 116b. The dielectric layer 126 may include one or more interlayer dielectric (ILD) layers, one or more etch stop layers (ESLs), and/or one or more of another type of dielectric layer. The dielectric layer 126 may include a silicon nitride (SiₓN_{y}), an oxide (e.g., a silicon oxide (SiOₓ) and/or another oxide material), and/or another type of dielectric material. The dielectric layer 126 may extend in the x-direction and/or in a y-direction in the semiconductor device 100.

A contact structure 128a (e.g., a gate contact) may be included in the dielectric layer 126 and may be electrically connected and/or physically connected with the gate structure 120 of the integrated circuit device 116a. Contact structures 128b and 128c (e.g., source/drain contacts) may be included in the dielectric layer 126 and may be electrically connected and/or physically connected with the source/drain regions 118a and 118b, respectively, of the integrated circuit device 116a.

A contact structure 128a (e.g., a gate contact) may be included in the dielectric layer 126 and may be electrically connected and/or physically connected with the gate structure 120 of the integrated circuit device 116b. Contact structures 128b and 128c (e.g., source/drain contacts) may be included in the dielectric layer 126 and may be electrically connected and/or physically connected with the source/drain regions 118a and 118b, respectively, of the integrated circuit device 116b.

The contact structures 128a-128c may each include one or more electrically conductive materials such as tungsten (W), cobalt (Co), ruthenium (Ru), titanium (Ti), an alloy thereof, a metal nitride that contains one or more metals, and/or another electrically conductive material. In some implementations, a liner is included between at least one of the contact structures 128a-128c and the dielectric layer 126. The liner may include an adhesion liner, a barrier liner, and/or another type of liner, and may include liner materials such as tantalum (Ta), tantalum nitride (TaN), and/or titanium nitride (TiN), among other examples.

In some implementations, metal silicide layers may be included on the source/drain region 118a and/or 118b of the integrated circuit device 116a and/or 116b. The metal silicide layers may each include a titanium silicide (TiSi), a ruthenium silicide (RuSi), and/or another type of metal silicide material. The metal silicide layers may provide a transition between the semiconductor material of the source/drain region 118a and/or 118b and the metal material of the associated contact structure. The metal silicide layers enable a low contact resistance to be achieved between the source/drain regions 118a and/or 118b and the associated contact structure.

As further shown in FIG. 1A, the semiconductor device 100 includes an isolation structure 130 that, in combination with the buried doped semiconductor layer 108 and the buried semiconductor layer extension regions 110, electrically isolate the high-voltage region 102 from other regions of the semiconductor device 100. The isolation structure 130 may laterally surround the high-voltage region 102 and the integrated circuit devices 116a and 116b included in the high-voltage region 102, and may provide electrical isolation for lateral current leakage to and/or from the high-voltage region 102.

The isolation structure 130 may include a deep trench isolation (DTI) structure that is elongated in the z-direction in the semiconductor device 100. The isolation structure 130 may extend through the semiconductor layer 106 and into a portion of the substrate layer 104 such that a bottom of the isolation structure 130 is located in the substrate layer 104. In some implementations, portions of an inner sidewall of the isolation structure 130 may be in contact with the buried doped semiconductor layer 108 and/or with the buried semiconductor layer extension regions 110.

The isolation structure 130 may include an elongated portion 132 and a capping portion 134. The capping portion 134 may be located above and/or on top of the elongated portion 132, and may have sides that extend laterally outward from the elongated portion 132. The elongated portion 132 includes one or more semiconductor liners, such as a buffer liner 136, a passivation liner 138, and/or a capping liner 140, among other examples. The semiconductor liners 136-140 may be included on the sidewalls and on the bottom surface of the elongated portion of the 132 of the isolation structure 130. The semiconductor liners 136-140 may correspond to a multi-layer liner that is included to passivate damage to the surrounding portions of the semiconductor layer 106 and of the substrate layer 104 that may have occurred due to etching of the semiconductor layer 106 and the substrate layer 104 to form the trench in which the isolation structure 130 was formed. In particular, the semiconductor liners 136-140 may be included to passivate dangling bonds in the semiconductor material (e.g., the silicon (Si) material) of semiconductor layer 106 and of the substrate layer 104 so that the dangling bonds do not act as charge-trapping sites, which would otherwise promote current leakage in the high-voltage region 102.

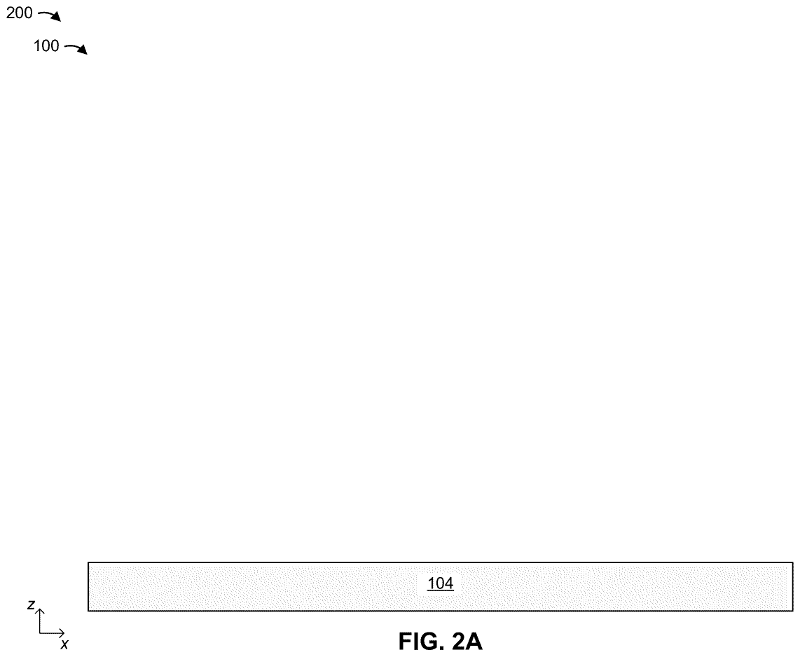

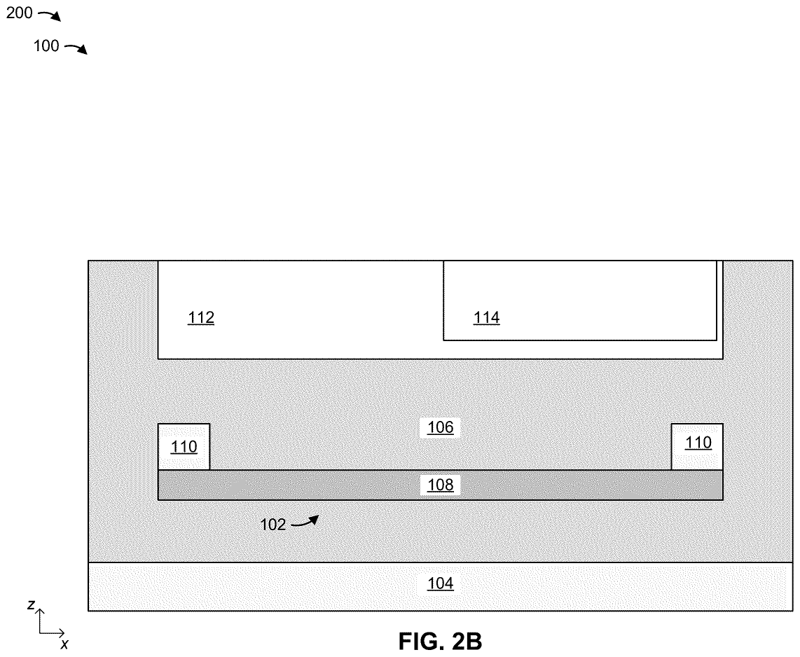

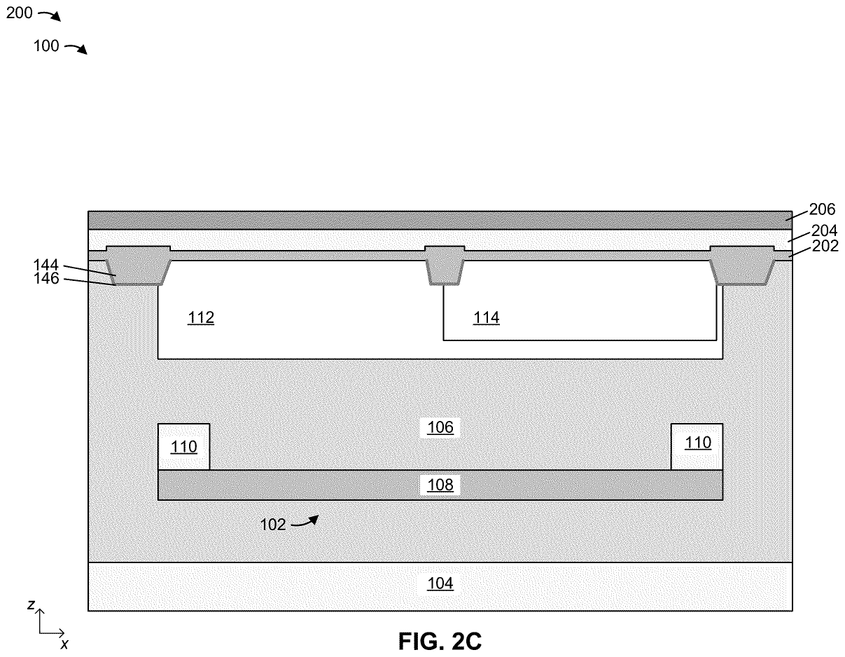

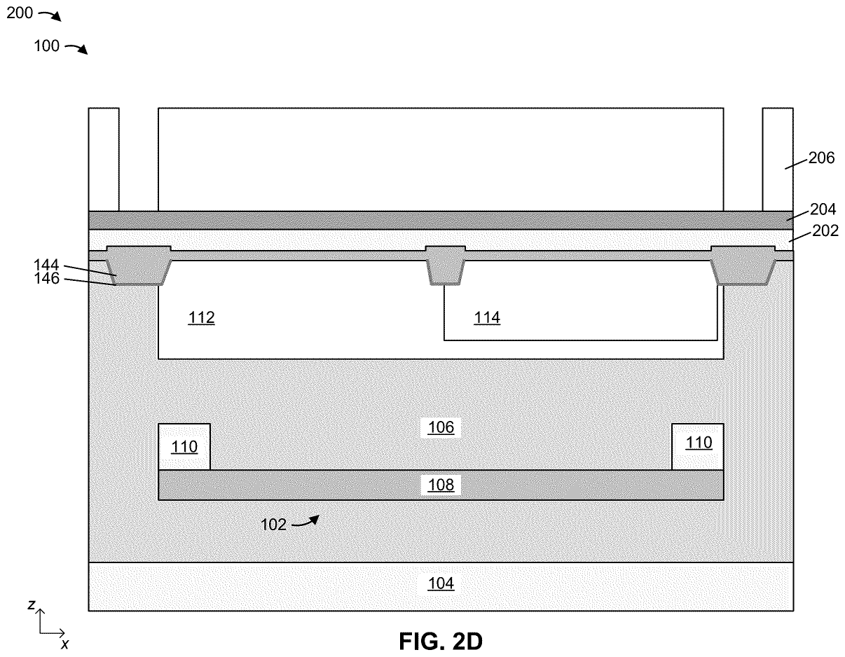

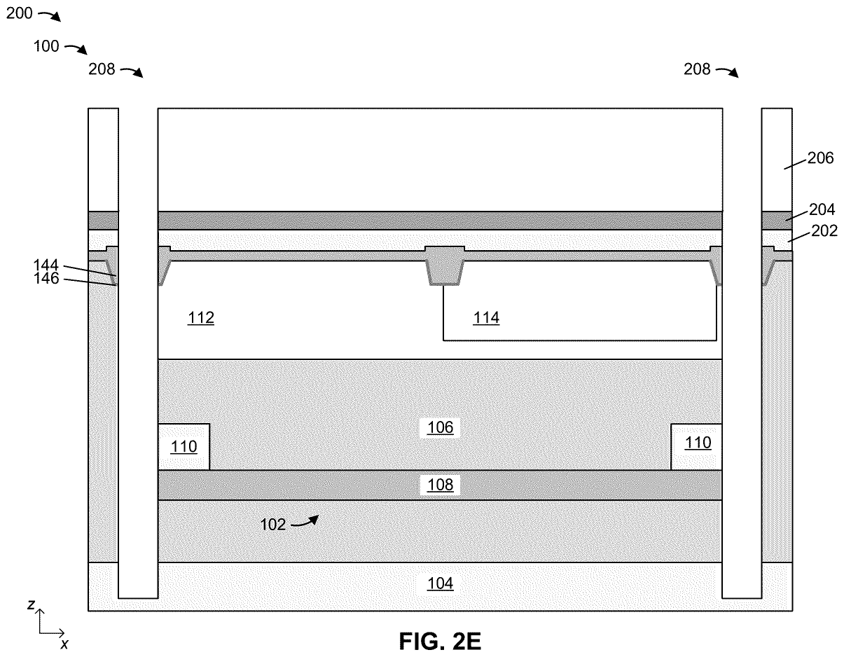

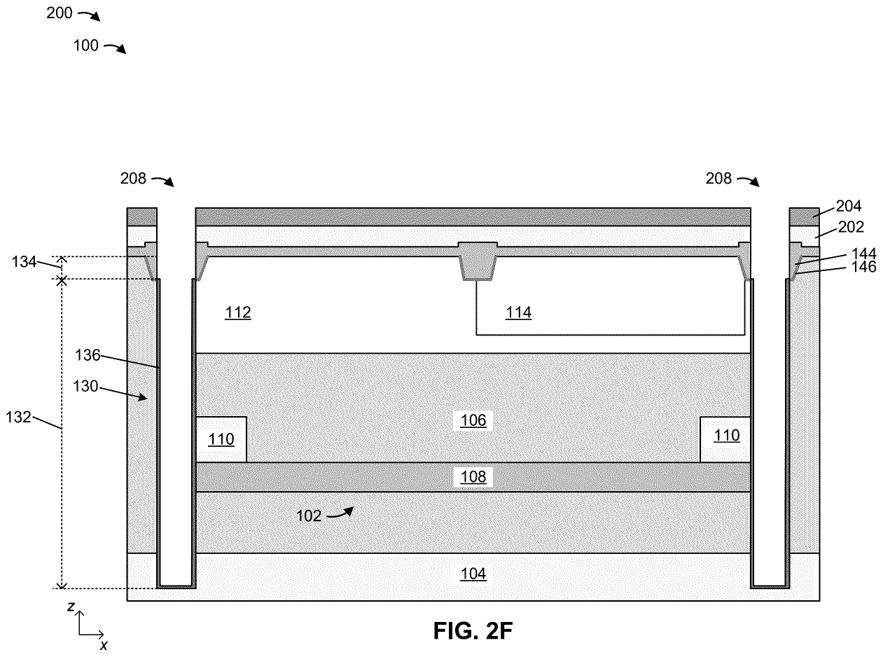

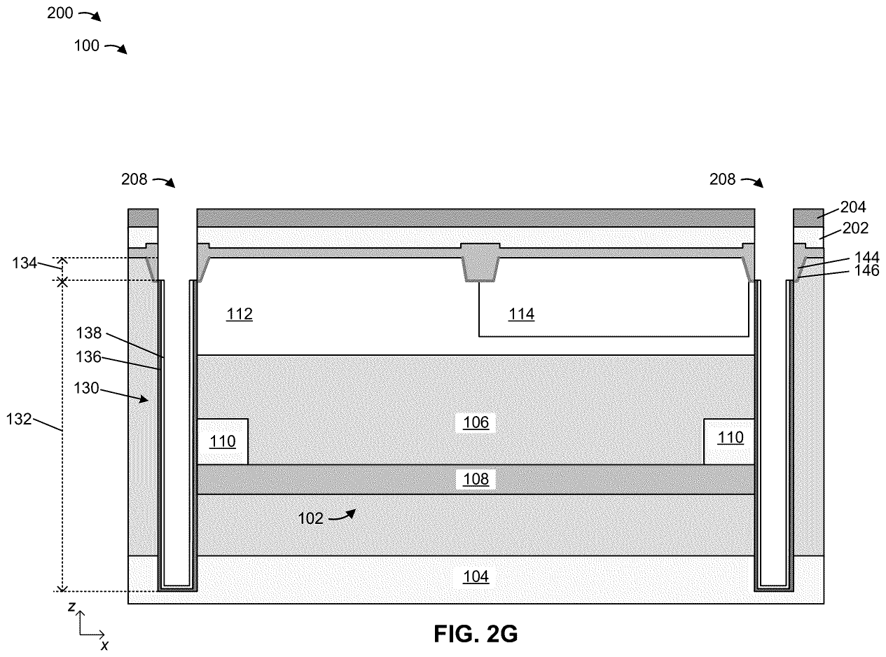

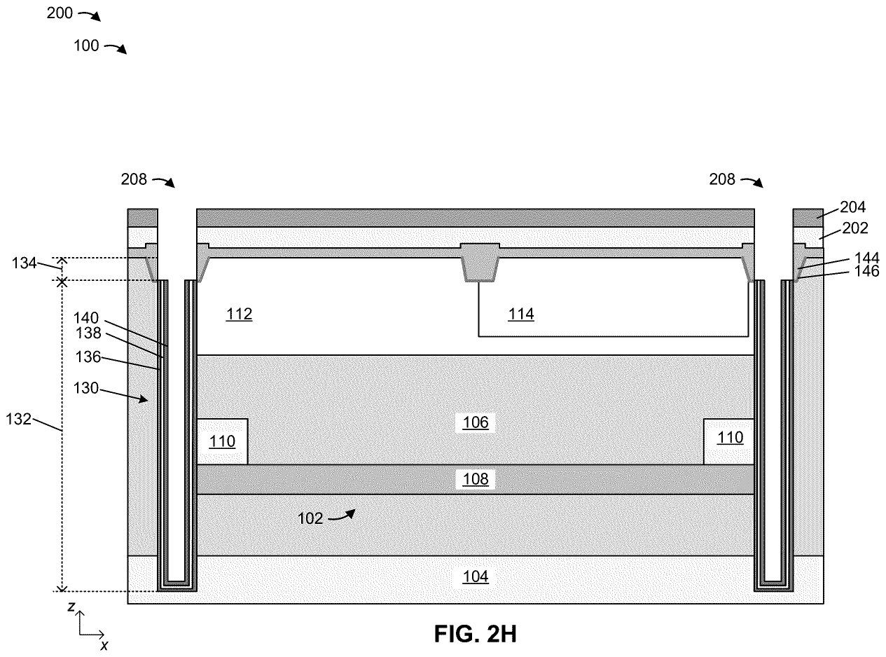

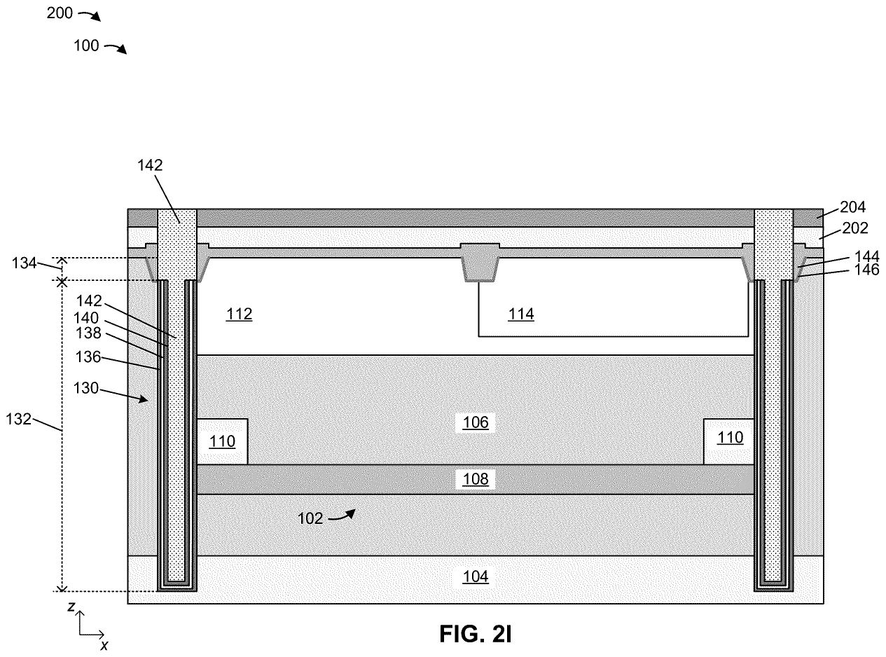

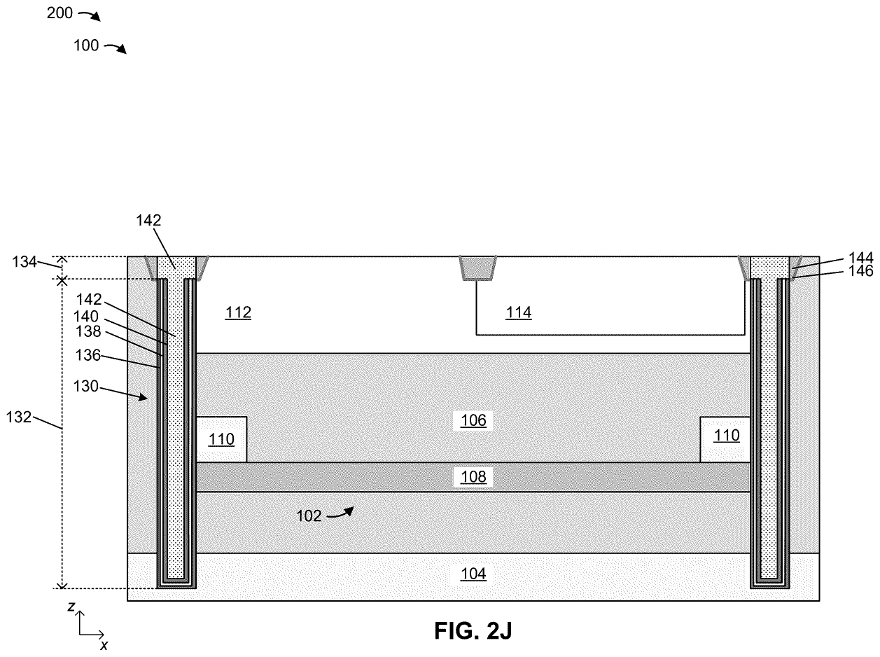

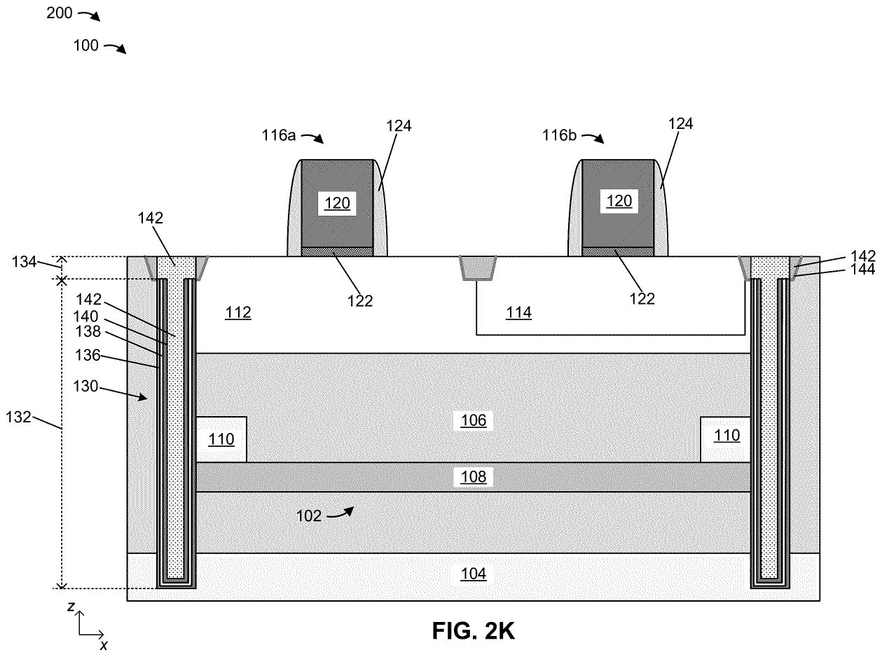

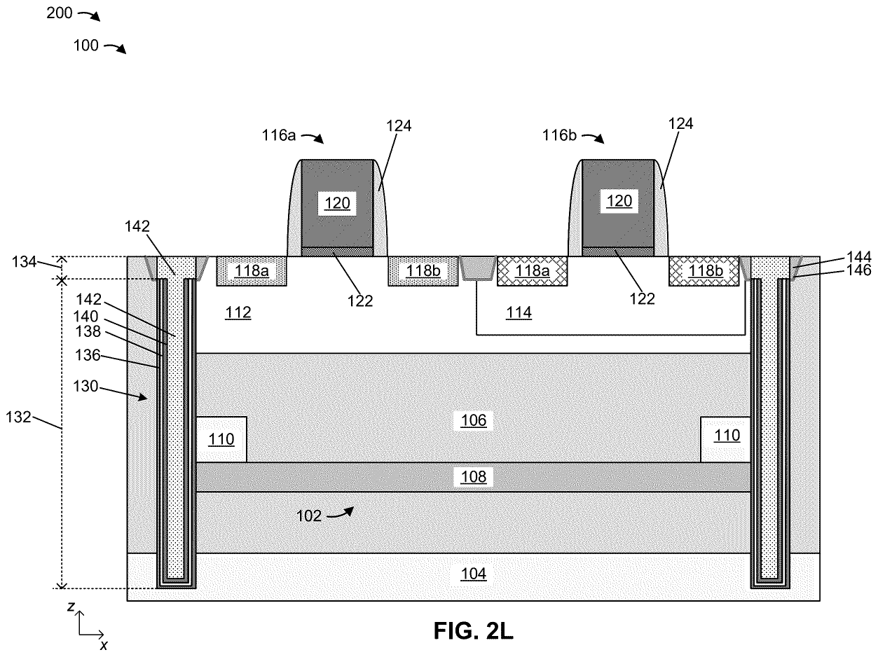

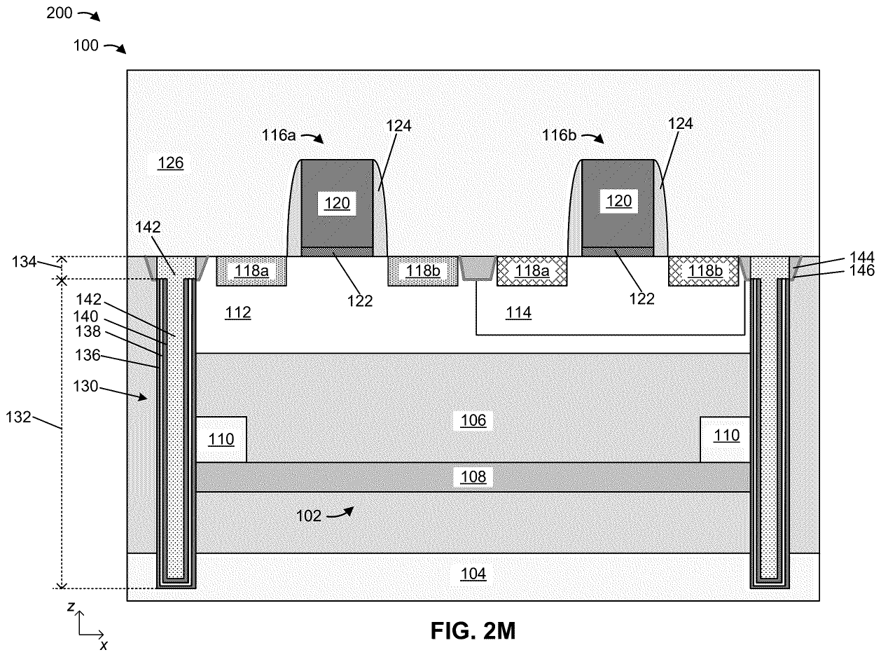

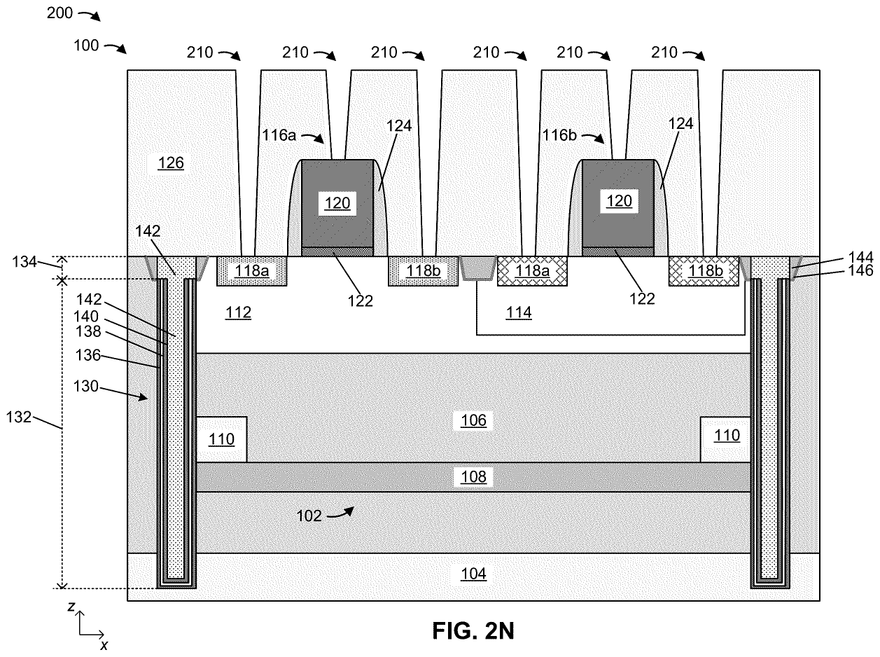

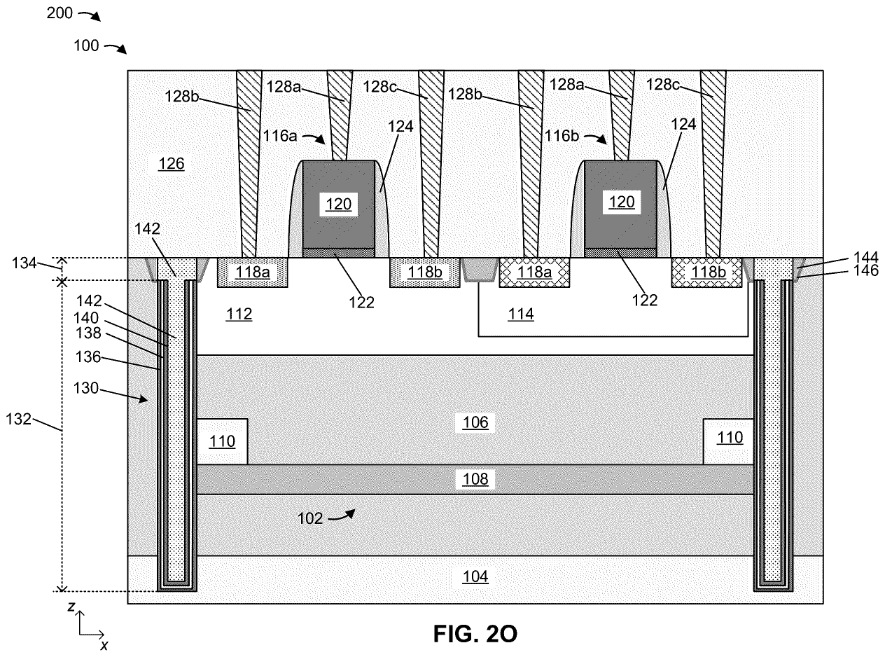

The cross-sectional profile of the elongated portion 132 and the capping portion 134 of the isolation structure 130 may result from selective epitaxial growth of one or more semiconductor liners 136-140, as described in greater detail in connection with FIGS. 2A-2O. The semiconductor liners 136-140 are grown by selective epitaxy in that the material of the semiconductor liners 136-140 selectively grows on the semiconductor material of the semiconductor layer 106 and of the substrate layer 104, whereas dielectric material of other layers and/or structures near the isolation structure 130 inhibit growth of the semiconductor liners 136-140. Thus, semiconductor liners 136-140 may be formed only in the elongated portion 132 of the isolation structure 130 and not in the capping portion 134 (which was formed in a surrounding dielectric structure).

The buffer liner 136, the passivation liner 138, and the capping liner 140 each include a semiconductor material. In some implementations, the buffer liner 136, the passivation liner 138, and the capping liner 140 each include the same base semiconductor material such as silicon (Si). The buffer liner 136 and the capping liner 140 may each be epitaxially grown from undoped silicon material, whereas the passivation liner 138 may be epitaxially grown from doped silicon material. However, some intermixing between the buffer liner 136, the passivation liner 138, and the capping liner 140 may occur, resulting in the buffer liner 136 and the capping liner 140 including some amount of the dopant of the passivation liner 138.

The passivation liner 138 may be doped with one or more n-type dopants that inhibit the attraction of electrons. Examples of such n-type dopants include phosphorous (P) and/or arsenic (As), among other examples. Thus, the semiconductor material of the passivation liner 138 may include phosphor-doped silicon (Si:P), arsenic-doped silicon (Si:As), and/or another n-type doped silicon. In some implementations, the n-type dopant concentration in the semiconductor material of the passivation liner 138 is included in a range of approximately 1×10¹⁸ dopant atoms per cubic centimeter to approximately 1×10²⁰ dopant atoms per cubic centimeter to provide effective passivation of the semiconductor layer 106 and the substrate layer 104 around the isolation structure 130. However, other values and ranges are within the scope of the present disclosure.

In some implementations, the material of the passivation liner 138 is also doped with carbon (C) in addition to the n-type dopant(s) to reduce or inhibit dopant diffusion into the surrounding portions of the semiconductor layer 106 and the substrate layer 104. For example, the semiconductor material of the passivation liner 138 may include phosphor-doped and carbon-doped silicon that is co-doped with carbon (Si:P:C), arsenic-doped and carbon-doped silicon (Si:As:C), and/or another n-type doped and carbon-doped silicon. In some implementations, the dopant concentration of n-type dopants and carbon dopants in the semiconductor material of the passivation liner 138 is included in a range of approximately 1×10¹⁸ dopant atoms per cubic centimeter to approximately 1×10²⁰ dopant atoms per cubic centimeter to provide effective passivation of the semiconductor layer 106 and the substrate layer 104 around the isolation structure 130, and to provide effective inhibiting of dopant diffusion. However, other values and ranges are within the scope of the present disclosure.

Alternatively, the semiconductor material of the passivation liner 138 may include another semiconductor material doped with n-type dopants and carbon. In some implementations, the semiconductor material of the passivation liner 138 is doped with p-type dopants and/or carbon.

The buffer liner 136 may be included between the passivation liner 138 and the semiconductor layer 106, and between the passivation liner 138 and the substrate layer 104. The buffer liner 136 may be included to inhibit diffusion of dopants from the passivation liner 138 into the semiconductor layer 106 and the substrate layer 104. In particular, the buffer liner 136 functions as a buffer of semiconductor material in which dopants from the passivation liner 138 may diffuse, as opposed to the dopants from the passivation liner 138 diffusing into the semiconductor layer 106 and/or into the substrate layer 102. In some implementations, the buffer liner 136 is in contact with the buried doped semiconductor layer 108 and/or with the buried semiconductor layer extension regions 110.

As further shown in FIG. 1A, the isolation structure 130 further includes an insert 142. A portion of the insert 142 may be included elongated portion 132, and another portion of the insert 142 may be included in the capping portion 134. In the elongated portion 132, the semiconductor liners 136-140 may be included between the insert 142 and the semiconductor layer 106, and between the insert 142 and the substrate layer 104. The capping liner 140 may be included between the insert 142 and the passivation liner 138, and may inhibit diffusion of dopants from the passivation liner 138 into the insert 142.

In the capping portion 134, another portion of the insert 142 may be located in and/or surrounded by a shallow trench isolation (STI) structure 144. The STI structure 144 may be formed of one or more dielectric materials such as silicon oxide (SiOₓ such as SiO₂) and/or silicon nitride (SiₓN_{y} such as Si₃N₄), which inhibit growth of semiconductor liners 136-140 in the capping portion 134 of the isolation structure 130. Thus, in some implementations, the capping portion 134 of the isolation structure 130 is free of the material(s) of the semiconductor liners 136-140, and the portion of the insert 142 in the capping portion 134 of the isolation structure 130 may be in contact with the STI structure 144.

In some implementations, the ends of the semiconductor liners 136-140 at the top of the elongated portion 132 may extend upward into the capping portion 134. This may occur not because the semiconductor liners 136-140 grow on the dielectric material of the STI structure 144, but that the material of the semiconductor liners 136-140 accumulate on themselves in multiple directions, including upward as well as outward from the semiconductor layer 106.

Because the capping portion 134 of the isolation structure 130 is substantially free of the material of the semiconductor liners 136-140, the portion of the insert 142 in the capping portion 134 may extend laterally outward from the portion of the insert 142 in the elongated portion 132. Thus, the portion of the insert 142 in the capping portion 134 may extend laterally over the ends of the semiconductor liners 136-140 at the top of the elongated portion 132. Thus, the insert 142 may have an overall approximate T-shaped cross-sectional profile.

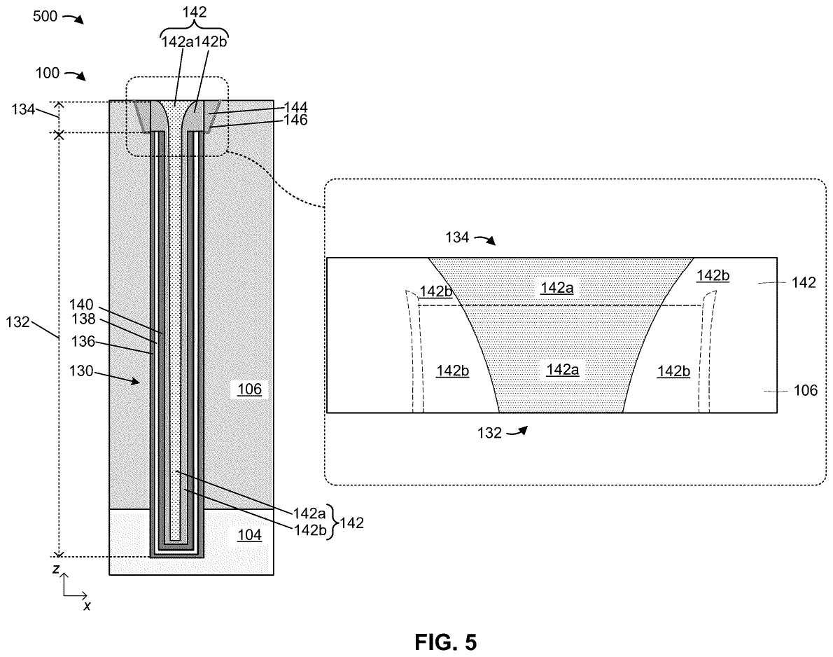

In some implementations, the insert 142 is a monolayer that is formed of polysilicon or doped polysilicon. In some implementations, and as illustrated in an example in FIG. 5, the insert 142 may be a two-part insert that include a plurality of layers of different material. For example, the insert 142 may include a dielectric layer and a polysilicon layer.

As further shown in FIG. 1A, one or more STI structures 144 may be included in the high-voltage region 102, in addition to being included above the elongated portion 132 of the isolation structure 130, to provide additional electrical isolation in the high-voltage region 102. The STI structures 144 may include an STI liner 146 between the STI structures 144 and the semiconductor layer 106, between the STI structures 144 and the first type doped well region 112, and/or between the STI structures 144 and the second type doped well region 114, among other examples.

As further shown in FIG. 1A, the isolation structure 130 may have one or more dimensions. An example dimension D1 may correspond to a vertical (z-direction) height of the isolation structure 130, which also corresponds to the vertical (z-direction) height of the insert 142. In some implementations, the vertical height of the isolation structure 130 (and the vertical height of the insert 142) may be included in a range of approximately 5 microns to approximately 50 microns so that the isolation structure 130 connects to the underlying buried doped semiconductor layer 108 (which provides for continuity of electrical isolation around the high-voltage region 102). However, other values and ranges are within the scope of the present disclosure.

Another example dimension D2 may correspond to a lateral width of the overall isolation structure 130 in a direction that is approximately orthogonal to a length of the isolation structure 130. For example, if the length of the isolation structure 130 is in the y-direction, the lateral width of the isolation structure 130 may be in the x-direction. As another example, if the length of the isolation structure 130 is in the x-direction, the lateral width of the isolation structure 130 may be in the y-direction. In some implementations, the lateral width of the isolation structure 130 may be included in a range of approximately 2 microns to approximately 3 microns. However, other values and ranges are within the scope of the present disclosure.

In some implementations, an aspect ratio of the isolation structure 130 (e.g., a ratio of the vertical (z-direction) height of the isolation structure 130 to the lateral width of the isolation structure 130) is included in a range of approximately 5:1 to approximately 25:1. However, other values and ranges are within the scope of the present disclosure.

Another example dimension D3 includes a thickness of the buffer liner 136 of the isolation structure 130. In some implementations, the thickness of the buffer liner 136 is included in a range of approximately 10 nanometers to approximately 50 nanometers to effectively inhibit migration from the passivation liner 138 into the semiconductor layer 106 and/or into substrate layer 104. However, other values and ranges are within the scope of the present disclosure.

Another example dimension D4 includes a thickness of the buffer liner 136 of the isolation structure 130. In some implementations, the thickness of the buffer liner 136 is included in a range of approximately 1 nanometer to approximately 100 nanometers to provide effective passivation for the portions of the semiconductor layer 106 and/or the portions of the substrate layer 104 around the isolation structure 130 so that a high breakdown voltage can be achieved for the integrated circuit devices 116a and 116b. However, other values and ranges are within the scope of the present disclosure.

Another example dimension D5 includes a thickness of the capping liner 140 of the isolation structure 130. In some implementations, the thickness of the capping liner 140 is included in a range of approximately 10 nanometers to approximately 50 nanometers to effectively inhibit migration from the passivation liner 138 into the insert 142. However, other values and ranges are within the scope of the present disclosure.

Another example dimension D6 includes a lateral width of the portion of the insert 142 in the elongated portion 132 of the isolation structure 130. Another example dimension D7 includes a lateral width of the portion of the insert 142 in the capping portion 134 of the isolation structure 130. The lateral width of the portion of the insert 142 in the capping portion 134 of the isolation structure 130 may be greater than the lateral width of the portion of the insert 142 in the elongated portion 132 of the isolation structure 130 (e.g., D7>D6) because of the inhibited growth of the semiconductor liners 136-140 in the capping portion 134.

As shown in FIG. 1B, the isolation structure may laterally surround the integrated circuit devices 116a and 116b in the high-voltage region 102, and may electrically isolate the integrated circuit devices 116a and 116b in the high-voltage region 102 from other regions of the semiconductor device 100. The first type doped well region 112 and the second type doped well region 114 may also be contained within the high-voltage region 102.

As further shown in FIG. 1B, the semiconductor liners 136-140 and the portion of the insert 142 in the elongated portion 132 of the isolation structure 130 may each conform to the overall closed-loop top view shape of the isolation structure 130. The capping portion 134 of the isolation structure 130 is omitted from FIG. 1B for clarity. The insert 142 may be included within a perimeter of outer segments 148 of the semiconductor liners 136-140, and inner segments 150 of the semiconductor liners 136-140 may be located within a perimeter of the insert 142.

As shown in the example in FIG. 1B, the closed-loop top view shape of the isolation structure 130 may an irregular hexagon shape that has angled corners. However, other closed-loop top view shapes for the isolation structure 130 are within the scope of the present disclosure, including rectangle shapes, square shapes, and/or non-standard/irregular shapes, among other examples.

As indicated above, FIGS. 1A and 1B are provided as an example. Other examples may differ from what is described with regard to FIGS. 1A and 1B.

FIGS. 2A-2O are diagrams of an example implementation 200 of forming a high-voltage region 102 in the semiconductor device 100 described herein. In some implementations, one or more of the operations described in connection with FIGS. 2A-2O may be performed using one or more semiconductor processing tools, such as a deposition tool, an exposure tool, a developer tool, an etch tool, an ion implantation tool, a planarization tool, and/or another suitable semiconductor processing tool.

As shown in FIG. 2A, the substrate layer 104 of the semiconductor device 100 may be provided. In some implementations, the substrate layer 104 may correspond to a portion of a semiconductor wafer (e.g., a silicon (Si) wafer, a silicon carbide (SiC) wafer). In some implementations, the substrate layer 104 may correspond to a portion of a semiconductor layer of a silicon-on-insulator (SOI) wafer. In some implementations, the substrate layer 104 may be provided in the form of another type of semiconductor workpiece.

As shown in FIG. 2B, various portions of the high-voltage region 102 may be formed above the substrate layer 104. For example, the semiconductor layer 106 may be formed above the substrate layer 104. As another example, the buried doped semiconductor layer 108 may be formed in the semiconductor layer 106. As another example, the buried semiconductor layer extension regions 110 may be formed above the buried doped semiconductor layer 108. As another example, the first type doped well region 112 may be formed above the buried doped semiconductor layer 108. As another example, the second type doped well region 114 may be formed above the buried doped semiconductor layer 108.

The semiconductor layer 106, the buried doped semiconductor layer 108, the buried semiconductor layer extension regions 110, the first type doped well region 112, and/or the second type doped well region 114 may be formed using various techniques such as ion implantation and epitaxy, among other examples. For example, a deposition tool may be used to perform an epitaxy operation to deposit (e.g., by epitaxial growth) a first portion of the semiconductor layer 106, and an ion implantation tool may be used to implant dopants into the first portion of the semiconductor layer 106 to form a first portion of the buried doped semiconductor layer 108.

As another example, a deposition tool may be used to perform an epitaxy operation to deposit (e.g., by epitaxial growth) a second portion of the semiconductor layer 106 on the first portion, and an ion implantation tool may be used to implant dopants into the second portion of the semiconductor layer 106 to form a second portion of the buried doped semiconductor layer 108 on the first portion. An ion implantation tool may be used to implant dopants into the second portion of the semiconductor layer 106 to form the buried semiconductor layer extension regions 110.

As another example, a deposition tool may be used to perform an epitaxy operation to deposit (e.g., by epitaxial growth) a third portion of the semiconductor layer 106 on the second portion, and an ion implantation tool may be used to implant dopants into the third portion of the semiconductor layer 106 to form the first type doped well region 112 and/or the second type doped well region 114.

In some implementations, the portions of the semiconductor layer 106 are formed to include different concentrations of dopants. For example, the portions of the semiconductor layer 106 may be formed such that a dopant concentration gradient is formed in the semiconductor layer 106. The dopant concentration gradient may result in the dopant concentration in the semiconductor layer 106 increasing from the first portion to the third portion through the second portion. However, other dopant profiles for the semiconductor layer 106 are within the scope of the present disclosure.

As shown in FIG. 2C, the STI structures 144 and the associated STI liner 146 may be formed in the semiconductor layer 106, including in the first type doped well region 112 and/or in the second type doped well region 114.

Forming the STI structures 144 and the STI liner 146 may include etching the semiconductor layer 106, the first type doped well region 112, and/or in the second type doped well region 114 to form recesses in the semiconductor layer 106, the first type doped well region 112, and/or in the second type doped well region 114. The material of the STI liner 146 may be conformally deposited in the recesses, and the recesses may be filled in with the material of the STI structures 144. In some implementations, excess material of the STI structures 144 is deposited such that the excess material extends above the recesses, and such that excess material of the STI structures 144 is deposited across the semiconductor layer 106.

In some implementations, a pattern in a photoresist layer is used to etch the semiconductor layer 106, the first type doped well region 112, and/or in the second type doped well region 114 to form the recesses. In these implementations, a deposition tool may be used to form the photoresist layer on the semiconductor device 100 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the semiconductor layer 106, the first type doped well region 112, and/or in the second type doped well region 114 to form recesses based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses based on a pattern.

A deposition tool may be used to deposit the material of the STI liner 146 on the sidewalls and bottom surfaces of the recesses using a conformal deposition technique such as chemical vapor deposition (CVD) and/or atomic layer deposition (ALD), among other examples. In some implementations, another deposition technique as a physical vapor deposition (PVD) is used to deposit the material of the STI liner 146 technique, an ALD technique, a CVD technique, an epitaxy technique, an oxidation technique, and/or another suitable deposition technique.

A deposition tool may be used to deposit the material of the STI structures 144 on the STI liner 146 in the recesses using a PVD technique, an ALD technique, a CVD technique, an oxidation technique, and/or another suitable deposition technique.

As further shown in FIG. 2C, a layer stack may be formed above the semiconductor layer 106, including above the STI structures 144. The layer stack may include one or more masking layers 202 and/or 204. The masking layers, 202, 204 of the layer stack may be used as a hard mask to etch the semiconductor layer 106 to form trenches in which the isolation structure 130 is to be formed.

In some implementations, the masking layers 202 and 204 each include a dielectric material. For example the masking layer 202 may include a high dielectric constant (high-k) dielectric material (e.g., a dielectric material having a dielectric constant greater than approximately 3.9), such as silicon nitride (SiₓN_{y}) and/or aluminum oxide (AlₓO_{y}), among other examples. As another example, the masking layer 204 may include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material.

A deposition tool may be used to deposit the material of the masking layers 202 and 204 using a PVD technique, an ALD technique, a CVD technique, an oxidation technique, and/or another suitable deposition technique. In some implementations, a planarization tool is used to perform a planarization operation (e.g., a chemical-mechanical planarization (CMP) operation) to planarize the masking layer 202 and/or the masking layer 204 after the masking layer 202 and/or the masking layer 204 is deposited.

In some implementations, the masking layer 202 is formed to a thickness that is included in a range of approximately 1000 angstroms to approximately 2000 angstroms. However, other ranges and values are within the scope of the present disclosure. In some implementations, the masking layer 204 is formed to a thickness that is included in a range of approximately 10000 angstroms to approximately 12000 angstroms. However, other ranges and values are within the scope of the present disclosure.

As shown in FIG. 2D, a photoresist layer 206 may be formed above the layer stack and patterned. A deposition tool may be used to form the photoresist layer 206 on the layer stack (e.g., using a spin-coating technique and/or another suitable deposition technique). In some implementations, the photoresist layer 206 is formed to a thickness that is included in a range of approximately 5 microns to approximately 6 microns. However, other values and ranges are within the scope of the present disclosure. An exposure tool may be used to expose the photoresist layer 206 to a radiation source to pattern the photoresist layer 206. A developer tool may be used to develop and remove portions of the photoresist layer 206 to expose the pattern in the photoresist layer 206.

As shown in FIG. 2E, one or more STI structures 144, the semiconductor layer 106, and the substrate layer 104 may be etched to form a trench 208 that laterally surrounds the high-voltage region 102 in a top view of the semiconductor device 100, similar to the top view of the isolation structure 130 shown in FIG. 1B. In some implementations, the pattern in the photoresist layer 206 may be used to etch the one or more STI structures 144, the semiconductor layer 106, and/or the substrate layer 104. In some implementations, the masking layers 202, 204 of the layer stack are etched based on the pattern in the photoresist layer 206 to transfer the pattern to the masking layer 202, 204, and the combination of the pattern in the photoresist layer 206 and in the masking layers 202, 204 is used to etch the one or more STI structures 144, the semiconductor layer 106, and the substrate layer 104 to form the trench 208.

In some implementations, the etch operation includes a dry etch operation, such as a plasma-based etch operation and/or a gas-based etch operation, may be used to anisotropically etch the one or more STI structures 144, the semiconductor layer 106, and the substrate layer 104 to form the trench 208. The use of the plasma-based etch technique minimizes lateral etching, resulting in substantially vertical sidewalls for the trench 208.

In some implementations, the etch operation includes a deep reactive ion etch process. For example, a first etch operation may be performed to form the trench 208 to a first depth. A protective layer may be formed on the sidewalls of the trench 208. The portion of the protective layer on the bottoms of the trench 208 may be removed, and a second operation may be performed to increase the depth of the trench 208 to a second depth. The protective layer may protect the sidewalls of the trench 208 from being etched, and therefore may prevent, minimize, and/or otherwise reduce lateral expansion of the trench 208. These operations may be performed for a plurality of cycles to form the trench 208 to have a high aspect ratio between the depth of the trench 208 and a lateral width of the trench 208.

The photoresist layer 206 may be subsequently removed from the semiconductor device 100. In some implementations, an ashing operation (e.g., a plasma ashing operation) may be performed to remove the photoresist layer 206. In some implementations, a chemical agent may be used to chemically strip the photoresist layer 206 from the semiconductor device 100.

As shown in FIG. 2F, the buffer liner 136 of the isolation structure 130 may be formed on the sidewalls and on the bottom surface of the trench 208. A deposition tool may be used to selectively grow the buffer liner 136 on sidewalls and on the bottom surface of the portion of the trench 208 under the STI structure(s) 144 corresponding to the elongated portion 132 of the isolation structure 130. An epitaxy technique maybe used to selectively grow the buffer liner 136 on portions of the substrate layer 104, portions of the semiconductor layer 106, portions of the buried doped semiconductor layer 108, portions of the buried doped semiconductor layer extension regions 110, portions of the first type doped well region 112, and/or portions of the second type doped well region 114 exposed in the trench 208. These portions were formed of semiconductor materials, and therefore provide a lattice-matched substrate to which the material of the buffer liner 136 aligns, thereby promoting crystal growth of the buffer liner 136.

In contrast, the dielectric material of the STI structures 144 in the top portion of the trench 208 corresponding to the capping portion 134 of the isolation structure 130 inhibits epitaxial growth of the semiconductor material of the buffer liner 136. The dielectric material of the STI structures 144 may have an amorphous crystal structure, and the amorphous crystal structure results in a large lattice mismatch between the amorphous crystal structure of the dielectric material of the STI structures 144 and the crystalline crystal structure of the semiconductor material of the buffer liner 136. This large lattice mismatch inhibits alignment of atoms in the semiconductor material of the buffer liner 136, which inhibits growth of the semiconductor material of the buffer liner 136 on the top portion of the trench 208.

As a result, the capping portion 134 of the isolation structure 130 may be free of the semiconductor material of the buffer liner 136. However, in some implementations, the ends of the buffer liner 136 at the top of the elongated portion 132 of the isolation structure 130 may grow upward into the capping portion 134 (in addition to growing laterally outward form the sidewalls of the trench 208), resulting in the ends of the buffer liner 136 extending into the capping portion 134 of the isolation structure 130.

As shown in FIG. 2G, the passivation liner 138 of the isolation structure 130 may be formed on the buffer liner 136 that is on the sidewalls and on the bottom surface of the trench 208. A deposition tool may be used to selectively grow the passivation liner 138 on sidewalls and on the bottom surface of the portion of the trench 208 under the STI structure(s) 144 corresponding to the elongated portion 132 of the isolation structure 130. An epitaxy technique maybe used to selectively grow the passivation liner 138 on the buffer liner 136, which functions as a crystal substrate for the passivation liner 138. In contrast, the dielectric material of the STI structures 144 in the top portion of the trench 208 corresponding to the capping portion 134 of the isolation structure 130 inhibits epitaxial growth of the doped semiconductor material of the passivation liner 138. As a result, the capping portion 134 of the isolation structure 130 may be free of the doped semiconductor material of the passivation liner 138. However, in some implementations, the ends of the passivation liner 138 at the top of the elongated portion 132 of the isolation structure 130 may grow upward into the capping portion 134 (in addition to growing laterally outward form the sidewalls of the trench 208), resulting in the ends of the passivation liner 138 extending into the capping portion 134 of the isolation structure 130.

As shown in FIG. 2H, the capping liner 140 of the isolation structure 130 may be formed on the passivation liner 138 that is on the sidewalls and on the bottom surface of the trench 208. A deposition tool may be used to selectively grow the capping liner 140 on sidewalls and on the bottom surface of the portion of the trench 208 under the STI structure(s) 144 corresponding to the elongated portion 132 of the isolation structure 130. An epitaxy technique maybe used to selectively grow the capping liner 140 on the passivation liner 138, which functions as a crystal substrate for the capping liner 140. In contrast, the dielectric material of the STI structures 144 in the top portion of the trench 208 corresponding to the capping portion 134 of the isolation structure 130 inhibits epitaxial growth of the undoped semiconductor material of the capping liner 140. As a result, the capping portion 134 of the isolation structure 130 may be free of the semiconductor material of the capping liner 140. However, in some implementations, the ends of the capping liner 140 at the top of the elongated portion 132 of the isolation structure 130 may grow upward into the capping portion 134 (in addition to growing laterally outward form the sidewalls of the trench 208), resulting in the ends of the capping liner 140 extending into the capping portion 134 of the isolation structure 130.

In some implementations, the operations described in connection with FIGS. 2F-2H to form the semiconductor liners 136-140 may be performed as part of single (continuous) epitaxy operation. For example, undoped semiconductor material (e.g., undoped silicon (Si)) may be deposited at the beginning of the epitaxy operation to form the buffer liner 136. The semiconductor material may be deposited using a silicon (Si) precursor such as dichlorosilane (DCS) may be used, along with one or more reactant gasses such as hydrochloric acid (HCl). The silicon precursor and/or the reactant may be introduced using a CVD technique such as low low-pressure CVD (LPCVD) and heated to a temperature that is included in a range of approximately 600 degrees Celsius to approximately 800 degrees Celsius to cause a reaction that results in silicon being deposited into the trench 208. In some implementations, a process pressure for depositing the silicon material may be included in a range of approximately 5 torr to approximately 500 torr. However, other values and ranges for the temperature and the pressure are within the scope of the present disclosure.

Semiconductor material may continue to be deposited as dopants are introduced to form the passivation liner 138. For example, a phosphorous precursor (P) such as phosphine (PH₃) may be introduced as an n-type dopant, and/or methylsilane (SiH₃CH₃) may be used as a precursor for achieving carbon-doped silicon. Along with the use of a reactant gas such as hydrochloric acid (HCl) and elevated temperature, a reactant may be achieved to deposit silicon doped with carbon and phosphorous.

Subsequently, the dopant source(s) are turned off so that undoped semiconductor material is again deposited to form the capping liner 140. Because the dopants are introduced in-situ and subsequently stopped, some intermixing of dopants may occur in the buffer liner 136 and in the capping liner 140. Thus, the buffer liner 136 and in the capping liner 140 may not be fully dopant free, and may contain some of the dopants that were used to form the passivation liner 138.

As shown in FIG. 2I, the remaining area in the trench 208 may be filled in with material of the insert 142. Thus, the insert 142 may extend through the elongated portion 132 of the isolation structure 130, and through the capping portion 134 of the isolation structure 130. The material of the insert 142 may be deposited on the capping liner 140 in the elongated portion 132 of the isolation structure 130, and may be deposited on the ends of the semiconductor liner 136-140 and in contact with the STI structure(s) 144 in the capping portion 134 of the isolation structure 130.

A deposition tool may be used to deposit the material of the insert 142 using a PVD technique, an ALD technique, a CVD technique, and/or another suitable deposition technique. The insert 142 may be deposited in one or more deposition operations. For example, the insert 142 may be deposited as a single polysilicon layer, or the insert 142 may be deposited as a two-part insert that includes a dielectric layer and a polysilicon layer deposited on the dielectric layer, among other examples.

As shown in FIG. 2J, a planarization tool may be used to perform a planarization operation (e.g., a CMP operation) to planarize the semiconductor device 100. The planarization operation may result in removal of the masking layers 202, 204 as well as of excess material of the STI structures 144. The tops of the inserts 142 of the isolation structure 130, the tops of the STI structures 144, and the top of the semiconductor layer 106 may be approximately co-planar after the planarization operation.

As shown in FIGS. 2K and 2L, the integrated circuit device 116a may be formed in and/or on the first type doped well region 112 within the perimeter of the isolation structure 130 (e.g., within the high-voltage region 102). The integrated circuit device 116b may be formed in and/or on the second type doped well region 114 within the perimeter of the isolation structure 130 (e.g., within the high-voltage region 102).

As shown in FIG. 2K, the gate dielectric layers 122 of the integrated circuit devices 116a, 116b may be formed above the semiconductor layer 106, and the gate structures 120 of the integrated circuit devices 116a, 116b may be formed on the gate dielectric layers 122.

To form the gate dielectric layers 122 and the gate structures 120, a gate stack may be formed above the semiconductor layer 106. A deposition tool may be used to deposit material of a gate dielectric layer and material of a gate layer using a PVD technique, a CVD technique, an ALD technique, an electroplating technique and/or another suitable deposition technique. In some implementations, a planarization tool may be used to perform a planarization operation (e.g., a CMP operation) to planarize the gate dielectric layer and/or the gate layer. The gate dielectric layer and the gate layer may be patterned and etched to define the gate dielectric layers 122 and the gate structures 120 of the integrated circuit devices 116a, 116b.

As further shown in FIG. 2K, the sidewall spacers 124 may be deposited (e.g., using a deposition tool) on the sidewalls of the gate structures 120 using a CVD technique, an ALD technique, a PVD technique, and/or another type of deposition technique. In some implementations, a spacer layer is blanket deposited over the semiconductor device 100 and then etched back to define the sidewall spacers 124.

As shown in FIG. 2L, the source/drain regions 118a and 118b of the integrated circuit devices 116a, 116b may be formed, using the gate structures 120 as a self-aligned mask. In some implementations, dummy gate structures are formed in place of the gate structures 120 in a similar manner as described in connection with FIG. 2K, and the dummy gate structures are used as the self-aligned mask to form the source/drain regions 118a and 118b. The dummy gate structures may then be removed and replaced with the gate structures 120.

As shown in FIG. 2L, the source/drain regions 118a and 118b of the integrated circuit device 116a may be formed in the first type doped well region 112, and source/drain regions 118a and 118b of the integrated circuit device 116b may be formed in the second type doped well region 114. An ion implantation tool may be used to dope portions of the first type doped well region 112 and portions of the second type doped well region 114 to form the source/drain regions 118a and 118b. Additionally and/or alternatively, portions of the first type doped well region 112 and portions of the second type doped well region 114 may be etched to form source/drain recesses, and semiconductor material may be epitaxially grown in the recesses to form the source/drain regions 118a and 118b. The semiconductor material (e.g., silicon (Si), gallium (Ga), or another type of semiconductor material) that is used to form the source/drain regions 118a and 118b may be doped with a p-type dopant (e.g., a type of dopant that includes electron acceptor atoms that create holes in the material), with an n-type dopant (e.g., a type of dopant that includes electron donor atoms that create mobile electrons in the material), and/or with another type of dopant.

As shown in FIG. 2M, the dielectric layer 126 may be formed over the semiconductor layer 106, over the gate structures 120, and over the isolations structure 130. Alternatively, the dielectric layer 126 may be formed over the dummy gate structures. The dummy gate structures may then be removed, leaving behind openings in the dielectric layer 126 in which the gate structures 120 may be formed.

A deposition tool may be used to deposit the dielectric layer 126 using a PVD technique, a CVD technique, an ALD technique, an oxidation technique, and/or another suitable deposition technique. In some implementations, a planarization tool is used to perform a CMP operation to planarize the dielectric layer 126.

As shown in FIGS. 2N and 2O, the contact structures 128a (e.g., gate contacts) may be formed over the gate structures 120 of the integrated circuit devices 116a, 116b such that the contact structures 128a land on the gate structures 120. The contact structures 128b (e.g., source/drain contacts) may be formed over the source/drain regions 118a of the integrated circuit devices 116a, 116b such that the contact structures 128b land on the source/drain regions 118a. The contact structures 128c (e.g., source/drain contact) may be formed over and/or on the source/drain regions 118b such that the contact structures 128c lands on the source/drain regions 118b.

As shown in FIG. 2N, recesses 210 may be formed in the dielectric layer 126 for the contact structures 128a-128c. For example, recesses 210 may be formed over the source/drain regions 118a to expose the source/drain regions 118a through the recesses. As another example, recesses 210 may be formed over the source/drain regions 118b to expose the source/drain regions 118b through the recesses 210. As another example, recess 210 may be formed over the gate structures 120 to expose the gate structures 120 through the recesses 210.

In some implementations, a pattern in a photoresist layer is used to etch the dielectric layer 126 to form the recesses 210. In these implementations, a deposition tool may be used to form the photoresist layer over the dielectric layer 126. An exposure tool may be used to expose the photoresist layer to a radiation source to pattern the photoresist layer. A developer tool may be used to develop and remove portions of the photoresist layer to expose the pattern. An etch tool may be used to etch the dielectric layer 126 to form the recesses 210. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recesses 210 based on a pattern.

As shown in FIG. 2O, a deposition tool may be used to deposit the material of the contact structures 128a-128c in the recesses using a CVD technique, a PVD technique, an ALD technique, an electroplating technique, and/or another suitable deposition technique. The contact structures 128a-128c may be deposited in one or more deposition operations. In some implementations, a seed layer is first deposited, and the contact structures 128a-128c are deposited on the seed layer. In some implementations, a liner is deposited in the recesses, and the contact structures 128a-128c are deposited on the liner in the recesses. The liner may include a barrier liner, an adhesion liner, and/or another suitable liner. Examples of liner materials include tantalum nitride (TaN), titanium nitride (TiN), and/or other suitable liner materials. In some implementations, a planarization tool is used to perform a planarization operation (e.g., a CMP operation) to planarize the contact structures 128a-128c after the contact structures 128a-128c are deposited.

As indicated above, FIGS. 2A-2O are provided as an example. Other examples may differ from what is described with regard to FIG. 2A-2O.

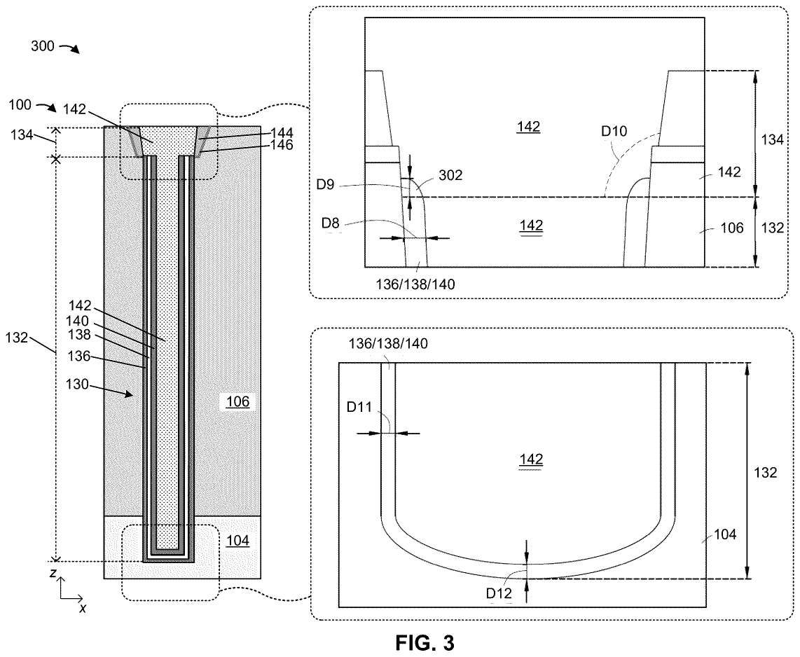

FIG. 3 illustrates an example implementation 300 of the isolation structure 130 described herein. In particular, FIG. 3 illustrates detailed views of a bottom portion of the elongated portion 132 of the example implementation 300 of the isolation structure 130, and of the capping portion 134 at the top of the elongated portion 132 of the example implementation 300 of the isolation structure 130.

As shown in FIG. 3, the example implementation 300 of the isolation structure 130 includes a similar combination and arrangement of layers and/or structures as the example implementation of the isolation structure 130 illustrated in FIGS. 1A and 1B. The example implementation 300 of the isolation structure 130 illustrated in FIG. 3 may be formed by similar operations as described in connection with FIGS. 2A-2O.

However, and as shown in the detailed view of the capping portion 134, the insert in the capping portion 134 may have angled sidewalls. The outward angle of the sidewalls of the insert 142 in the capping portion 134 may result from etch loading at the top of the trench 208 when forming the trench 208. Thus, the insert 142 in the capping portion 134 may conform to the tapered sidewalls at the top of the trench 208.

As further shown in the detailed view of the capping portion 134, the combination of the semiconductor liners 136-140 may have a thickness at the top of the elongated portion 132 (indicated as a dimension D8). The thickness of the combination of the semiconductor liners 136-140 at the top of the elongated portion 132 may be in a direction that is approximately perpendicular to the planar surface of the sidewalls of the elongated portion 132 of the isolation structure 130. In some implementations, the thickness of the combination of the semiconductor liners 136-140 at the top of the elongated portion 132 may be included in a range of approximately 1 nanometer to approximately 100 nanometers. However, other values and ranges are within the scope of the present disclosure In some implementations, the thickness of the combination of the semiconductor liners 136-140 at the top of the elongated portion 132 is greater than approximately 100 nanometers.

As further shown in the detailed view of the capping portion 134, the ends 302 of the semiconductor liners 136-140 at the top of the elongated portion 132 may extend upward into the capping portion 134. The distance that the ends 302 extend into the capping portion 134 (indicated as a dimension D9) may be included in a range of approximately 1 nanometer to approximately 30 nanometers. However, other values and ranges are within the scope of the present disclosure.

As further shown in the detailed view of the capping portion 134, the insert 142 in the capping portion 134 may have an angle (indicated as a dimension D10) between a bottom of the insert 142 in the capping portion 134 (e.g., which may be substantially in an x-y plane in the semiconductor device). In some implementations, the angle of the sidewalls of the insert 142 in the capping portion 134 may be greater than approximately 90 degrees. However, other values are within the scope of the present disclosure.

As shown in the detailed view of the bottom of the elongated portion 132, the combination of the semiconductor liners 136-140 on the sidewall at the bottom of the elongated portion 132 may have a thickness indicated in FIG. 3 as a dimension D11. The thickness of the combination of the semiconductor liners 136-140 on the sidewall at the bottom of the elongated portion 132 may be in a direction that is approximately perpendicular to the planar surface of the sidewalls of the elongated portion 132 of the isolation structure 130.

As further shown in the detailed view of the bottom of the elongated portion 132, the combination of the semiconductor liners 136-140 on the bottom surface of the elongated portion 132 of the isolation structure 130 may have a thickness indicated in FIG. 3 as a dimension D12. The thickness of the combination of the semiconductor liners 136-140 on the bottom surface of the elongated portion 132 of the isolation structure 130 may be in a direction that is approximately perpendicular to a tangent line at a particular location along the bottom surface.

In some implementations, the thickness of the combination of the semiconductor liners 136-140 on the sidewall at the bottom of the elongated portion 132, and the thickness of the combination of the semiconductor liners 136-140 on the bottom surface of the elongated portion 132, may each be included in a range of approximately 1 nanometer to approximately 100 nanometers. However, other values and ranges are within the scope of the present disclosure In some implementations, the thickness of the combination of the semiconductor liners 136-140 on the sidewall at the bottom of the elongated portion 132, and/or the thickness of the combination of the semiconductor liners 136-140 on the bottom surface of the elongated portion 132, may be greater than approximately 100 nanometers.

The epitaxial techniques described in connection with FIGS. 2F-2H that were used to form the semiconductor liners 136-140 may result in a particular loading profile for the semiconductor liners 136-140. In particular, the pressure used in the epitaxially growth of the semiconductor liners 136-140, as described in connection with FIGS. 2F-2H, may result in the thickness of the combination of the semiconductor liners 136-140 at the top of the elongated portion 132 being greater than the thickness of the combination of the semiconductor liners 136-140 on the sidewall at the bottom of the elongated portion 132 (e.g., D8>D11), and being greater than the thickness of the combination of the semiconductor liners 136-140 on the bottom surface of the elongated portion 132 (e.g., D8>12). Moreover, the pressure used in the epitaxially growth of the semiconductor liners 136-140, as described in connection with FIGS. 2F-2H, may result in the thickness of the combination of the semiconductor liners 136-140 on the bottom surface of the elongated portion 132 being greater than the thickness of the combination of the semiconductor liners 136-140 on the sidewall at the bottom of the elongated portion 132 (e.g., D12>D11). However, other loading profiles for the semiconductor liners 136-140 are within the scope of the present disclosure.

As indicated above, FIG. 3 is provided as an example. Other examples may differ from what is described with regard to FIG. 3.

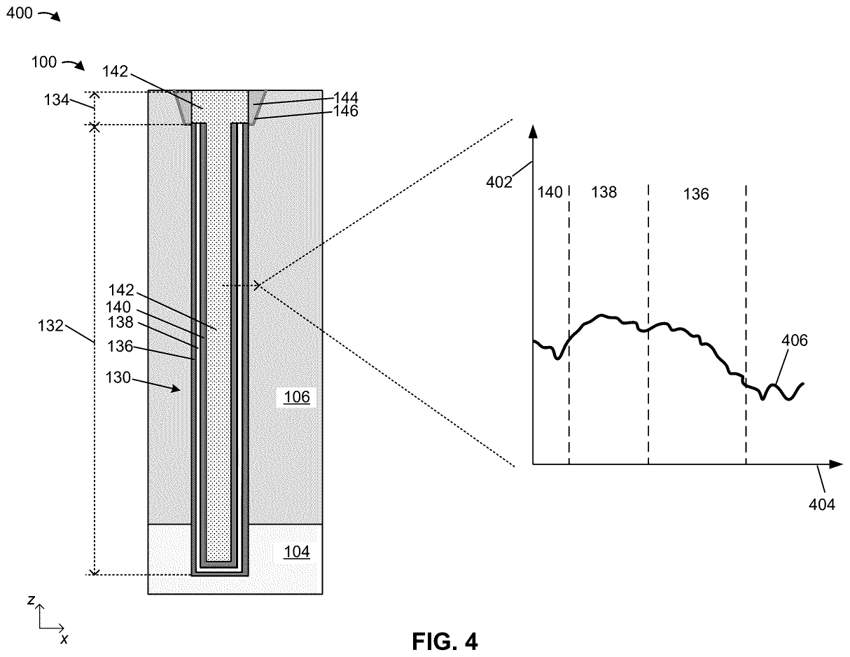

FIG. 4 illustrates an example implementation 400 of a dopant composition 402 of the semiconductor liners 136-140 of the isolation structure 130 described herein. As shown in FIG. 4, the dopant composition 402 of the semiconductor liners 136-140 of the isolation structure 130 is illustrated along a direction 404 that is across the semiconductor liners 136-140.

As shown in FIG. 4, the dopant composition 402 for dopant(s) 406 in the semiconductor liners 136-140 may be highest in the passivation liner 138. The dopant(s) 406 may include n-type dopants and/or carbon (or another type of dopant) that were introduced during deposition (e.g., during epitaxial growth) of the material of the passivation liner 138. During and/or after the epitaxy operation for the passivation liner 138, some of the dopant(s) 406 may diffuse into the buffer liner 136 and/or into the capping liner 140. Thus, the dopant composition 402 for dopant(s) 406 may decrease into the buffer liner 136 from the interface between the buffer liner 136 and the passivation liner 138, and may decrease into the capping liner 140 from the interface between the capping liner 140 and the passivation liner 138. Moreover, some of the dopant(s) 406 may diffuse into the surrounding portions of the semiconductor layer 106 and/or the surrounding portions of the substrate layer 104.

As indicated above, FIG. 4 is provided as an example. Other examples may differ from what is described with regard to FIG. 4.

FIG. 5 illustrates an example implementation 500 of the isolation structure 130 described herein. As shown in FIG. 5, the example implementation 500 of the isolation structure 130 includes a similar combination and arrangement of layers and/or structures as the example implementation of the isolation structure 130 illustrated in FIGS. 1A and 1B. The example implementation 500 of the isolation structure 130 illustrated in FIG. 5 may be formed by similar operations as described in connection with FIGS. 2A-2O.

However, as shown in FIG. 5, the example implementation 500 of the isolation structure 130 includes a two-part insert 142. The two-part insert 142 may include a polysilicon core 142a and a dielectric cladding 142b around the polysilicon core 142a. The capping liner 140 may be in contact with the dielectric cladding 142b, and the dielectric cladding 142b may be between the capping liner 140 and the polysilicon core 142a.

The polysilicon core 142a may include an undoped polysilicon material, a p-type doped polysilicon material, an n-type doped polysilicon material, and/or another type of polysilicon material. In some implementations, the dielectric cladding 142b may include a high-k dielectric material such as silicon nitride (SiₓN_{y}) and/or aluminum oxide (AlₓO_{y}), among other examples. In some implementations, the dielectric cladding 142b may include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material.

As shown in a detailed view in FIG. 5, the polysilicon core 142a and/or the dielectric cladding 142b may be angled, curved, and/or tapered in a similar manner as the insert in the example implementation 300 of the isolation structure 130 in FIG. 3. In some implementations, the curvature of the sidewalls of the polysilicon core 142a and/or of the sidewalls of the dielectric cladding 142b may extend into the top of the elongated portion 132 of the isolation structure, as shown in the example in FIG. 5.

As indicated above, FIG. 5 is provided as an example. Other examples may differ from what is described with regard to FIG. 5.

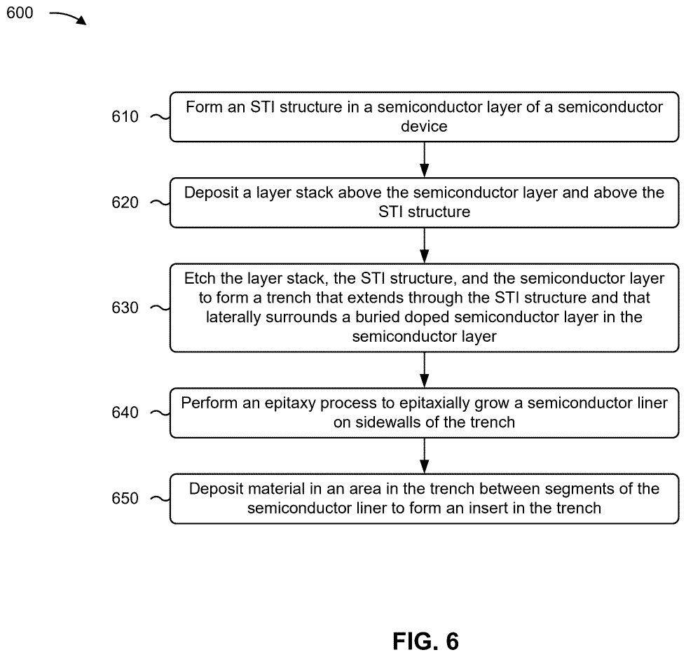

FIG. 6 is a flowchart of an example process 600 associated with forming a semiconductor device described herein. In some implementations, one or more process blocks of FIG. 6 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 6, process 600 may include forming an STI structure in a semiconductor layer of a semiconductor device (block 610). For example, one or more semiconductor processing tools may be used to form an STI structure (e.g., an STI structure 144) in a semiconductor layer (e.g., a semiconductor layer 106) of a semiconductor device (e.g., a semiconductor device 100), as described herein.

As further shown in FIG. 6, process 600 may include depositing a layer stack above the semiconductor layer and above the STI structure (block 620). For example, one or more semiconductor processing tools may be used to deposit a layer stack (e.g., a layer stack that includes a masking layer 202 and/or a masking layer 204) above the semiconductor layer and above the STI structure, as described herein.

As further shown in FIG. 6, process 600 may include etching the layer stack, the STI structure, and the semiconductor layer to form a trench that extends through the STI structure and that laterally surrounds a buried doped semiconductor layer in the semiconductor layer (block 630). For example, one or more semiconductor processing tools may be used to etch the layer stack, the STI structure, and the semiconductor layer to form a trench (e.g., a trench 208) that extends through the STI structure and that laterally surrounds a buried doped semiconductor layer (e.g., a buried doped semiconductor layer 108) in the semiconductor layer, as described herein. In some implementations, a bottom of the trench is lower in the semiconductor layer than the buried doped semiconductor layer.

As further shown in FIG. 6, process 600 may include performing an epitaxy process to epitaxially grow a semiconductor liner on sidewalls of the trench (block 640). For example, one or more semiconductor processing tools may be used to perform an epitaxy process to epitaxially grow a semiconductor liner (e.g., a buffer liner 136, a passivation liner 138, a capping liner 140) on sidewalls of the trench, as described herein. In some implementations, performing the epitaxy process includes performing the epitaxy process to epitaxially grow a multi-layer semiconductor liner (e.g., that includes the buffer liner 136, the passivation liner 138, and the capping liner 140) on the sidewalls of the trench. In some implementations, dielectric material of the STI structure resists growth of the multi-layer semiconductor liner on the STI structure.

As further shown in FIG. 6, process 600 may include depositing material in an area in the trench between segments of the semiconductor liner to form an insert in the trench (block 650). For example, one or more semiconductor processing tools may be used to deposit material in an area in the trench between segments of the semiconductor liner to form an insert (e.g., an insert 142) in the trench, as described herein. In some implementations, the segments of the semiconductor liner and the insert correspond to an elongated isolation structure in the semiconductor that laterally surrounds the buried doped semiconductor layer. In some implementations, an elongated portion (e.g., an elongated portion 132) of the insert under the STI structure has a first lateral width (e.g., a dimension D6) in a direction that is approximately perpendicular to a length of the elongated isolation structure. In some implementations, a capping portion (e.g., a capping portion 134) of the insert in the STI structure has a second lateral width (e.g., a dimension D7) in the direction that is approximately perpendicular to the length of the elongated isolation structure. In some implementations, the second lateral width is greater than the first lateral width.

Process 600 may include additional implementations, such as any single implementation or any combination of implementations described below and/or in connection with one or more other processes described elsewhere herein.

In a first implementation, performing the epitaxy process to grow the semiconductor liner includes performing the epitaxy process to epitaxially grow a doped silicon passivation liner (e.g., a passivation liner 138) on the sidewalls of the trench.

In a second implementation, alone or in combination with the first implementation, performing the epitaxy process to grow the semiconductor liner includes performing the epitaxy process to epitaxially grow an undoped silicon (Si) liner (e.g., a buffer liner 136) on the sidewalls of the trench, and to grow a doped silicon passivation liner (e.g., a passivation liner 138) on the undoped silicon liner.

In a third implementation, alone or in combination with one or more of the first and second implementations, performing the epitaxy process to grow the semiconductor liner includes performing the epitaxy process to epitaxially grow an undoped silicon (Si) liner (e.g., a buffer liner 136) on the sidewalls of the trench, to epitaxially grow a doped silicon passivation liner (e.g., a passivation liner 138) on the undoped silicon liner, and to epitaxially grow a silicon capping liner (e.g., a capping liner 140) on the doped silicon passivation liner.

In a fourth implementation, alone or in combination with one or more of the first through third implementations, the doped silicon passivation liner includes a phosphor-doped silicon (SiP).

In a fifth implementation, alone or in combination with one or more of the first through fourth implementations, the doped silicon passivation liner includes a phosphor-doped and carbon-doped silicon (SiP/C).

In a sixth implementation, alone or in combination with one or more of the first through fifth implementations, a portion of the semiconductor liner grows on an end of the buried doped semiconductor layer.

In a seventh implementation, alone or in combination with one or more of the first through sixth implementations, etching the layer stack, the STI structure, and the semiconductor layer to form the trench includes etching into a portion of a substrate layer (e.g., a substrate layer 104) under the semiconductor layer such that a bottom of the trench is located in the substrate layer, and performing the epitaxy process to epitaxially grow the semiconductor liner includes performing the epitaxy process to epitaxially grow the semiconductor liner on the substrate layer at the bottom of the trench.

In an eight implementation, alone or in combination with one or more of the first through seventh implementations, the capping portion extends laterally over ends (e.g., ends 302) of the semiconductor liner.

In a ninth implementation, alone or in combination with one or more of the first through eighth implementations, process 600 includes an STI structure (e.g., an STI structure 144) in the semiconductor layer, the DTI structure extends through the STI structure, and the capping portion of the two-part insert is located in the STI structure.

In a tenth implementation, alone or in combination with one or more of the first and ninth implementations, ends (e.g., ends 302) of the semiconductor liner are located above a bottom surface of the STI structure.

In an eleventh implementation, alone or in combination with one or more of the first through tenth implementations, the semiconductor liner comprises a silicon (Si) buffer layer (e.g., a buffer liner 136), a doped silicon passivation layer (e.g., a passivation liner 138) on the silicon buffer layer, and a silicon capping liner (e.g., a capping liner 140) on the silicon buffer layer.

In a twelfth implementation, alone or in combination with one or more of the first through eleventh implementations, a first thickness (e.g., a dimension D8) of the semiconductor liner at a top of the DTI structure is greater than a second thickness (e.g., a dimension D11) at a bottom of the DTI structure.

In a thirteenth implementation, alone or in combination with one or more of the first through twelfth implementations, a third thickness (e.g., a dimension D8) of the semiconductor liner between a bottom surface of the elongated portion of the two-part insert and the substrate layer is greater than the second thickness.

In a fourteenth implementation, alone or in combination with one or more of the first through thirteenth implementations, an angle (e.g., a dimension D10) between a sidewall of the capping portion of the two-part insert, and a bottom surface of the capping portion, is greater than approximately 90 degrees.

Although FIG. 6 shows example blocks of process 600, in some implementations, process 600 includes additional blocks, fewer blocks, different blocks, or differently arranged blocks than those depicted in FIG. 6. Additionally, or alternatively, two or more of the blocks of process 600 may be performed in parallel.

In this way, an isolation structure for a high-voltage region of a semiconductor device may be manufactured using self-aligned doping techniques to reduce the time, cost, and/or complexity of manufacturing the isolation structure. As described herein, a trench may be formed in and/or through a semiconductor layer of the semiconductor device. One or more self-aligned epitaxy operations may be performed to epitaxially grow one or more semiconductor liners on the sidewalls of the trench. The trench may then be filled in with material of an insert. The semiconductor liner(s) and the insert correspond to the isolation structure, and the isolation structure laterally surrounds the high-voltage region of the semiconductor device. The use of the self-aligned epitaxy technique described herein may be more cost effective and less complex than other techniques such as two-part ion implantation. Moreover, the use of the self-aligned epitaxy technique described herein enables the formation of the semiconductor liner(s) to be highly controlled, which provides for a high amount of control over film thickness, contamination, and defect rate for the semiconductor liner(s). This enables a low defect rate to be achieved for the isolation liner, and enables the isolation liner to better withstand high breakdown voltages than if the isolation structure were formed using other process techniques.

As described in greater detail above, some implementations described herein provide a method. The method includes forming an STI structure in a semiconductor layer of a semiconductor device. The method includes depositing a layer stack above the semiconductor layer and above the STI structure. The method includes etching the layer stack, the STI structure, and the semiconductor layer to form a trench that extends through the STI structure and that laterally surrounds a buried doped semiconductor layer in the semiconductor layer, where a bottom of the trench is lower in the semiconductor layer than the buried doped semiconductor layer. The method includes performing an epitaxy process to epitaxially grow a semiconductor liner on sidewalls of the trench. The method includes depositing material in an area in the trench between segments of the semiconductor liner to form an insert in the trench, where the segments of the semiconductor liner and the insert correspond to an elongated isolation structure in the semiconductor that laterally surrounds the buried doped semiconductor layer.

As described in greater detail above, some implementations described herein provide a semiconductor device. The semiconductor device includes a substrate layer. The semiconductor device includes a semiconductor layer above the substrate layer. The semiconductor device includes a buried doped semiconductor layer in the semiconductor layer. The semiconductor device includes one or more transistor structures above the buried doped semiconductor layer. The semiconductor device includes a DTI structure in the semiconductor layer. The closed-loop shape of the DTI structure laterally surrounds the buried doped semiconductor layer and the one or more transistor structures. The DTI structure includes a two-part insert. The two-part insert includes an elongated portion. The two-part insert includes a capping portion above the elongated portion. The semiconductor device includes a semiconductor liner between sidewalls of the elongated portion and the semiconductor layer.

As described in greater detail above, some implementations described herein provide a method. The method includes forming an STI structure in a semiconductor layer of a semiconductor device. The method includes depositing a layer stack above the semiconductor layer and above the STI structure. The method includes etching the layer stack, the STI structure, and the semiconductor layer to form a trench that extends through the STI structure and that laterally surrounds a buried doped semiconductor layer in the semiconductor layer, where a bottom of the trench is lower in the semiconductor layer than the buried doped semiconductor layer. The method includes performing an epitaxy process to epitaxially grow a multi-layer semiconductor liner on sidewalls of the trench, where dielectric material of the STI structure resists growth of the multi-layer semiconductor liner on the STI structure. The method includes depositing material in an area in the trench between segments of the semiconductor liner to form an insert in the trench, where the segments of the semiconductor liner and the insert correspond to an elongated isolation structure in the semiconductor that laterally surrounds the buried doped semiconductor layer, where an elongated portion of the insert under the STI structure has a first lateral width in a direction that is approximately perpendicular to a length of the elongated isolation structure, where a capping portion of the insert in the STI structure has a second lateral width in the direction that is approximately perpendicular to the length of the elongated isolation structure, and where the second lateral width is greater than the first lateral width.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a shallow trench isolation (STI) structure in a semiconductor layer of a semiconductor device;
depositing a layer stack above the semiconductor layer and above the STI structure;
etching the layer stack, the STI structure, and the semiconductor layer to form a trench that extends through the STI structure and that laterally surrounds a buried doped semiconductor layer in the semiconductor layer,
wherein a bottom of the trench is lower in the semiconductor layer than the buried doped semiconductor layer;
performing an epitaxy process to epitaxially grow a semiconductor liner on sidewalls of the trench; and
depositing material in an area in the trench between segments of the semiconductor liner to form an insert in the trench,
wherein the segments of the semiconductor liner and the insert correspond to an elongated isolation structure in the semiconductor that laterally surrounds the buried doped semiconductor layer.

2. The method of claim 1, wherein performing the epitaxy process to grow the semiconductor liner comprises:
performing the epitaxy process to epitaxially grow a doped silicon passivation liner on the sidewalls of the trench.

3. The method of claim 1, wherein performing the epitaxy process to grow the semiconductor liner comprises:
performing the epitaxy process to epitaxially grow an undoped silicon (Si) liner on the sidewalls of the trench, and to grow a doped silicon passivation liner on the undoped silicon liner.

4. The method of claim 1, wherein performing the epitaxy process to grow the semiconductor liner comprises:
performing the epitaxy process to epitaxially grow an undoped silicon (Si) liner on the sidewalls of the trench, to epitaxially grow a doped silicon passivation liner on the undoped silicon liner, and to epitaxially grow a silicon capping liner on the doped silicon passivation liner.

5. The method of claim 4, wherein the doped silicon passivation liner comprises a phosphor-doped silicon (Si:P).

6. The method of claim 4, wherein the doped silicon passivation liner comprises a phosphor-doped and carbon-doped silicon (Si:P/C).

7. The method of claim 1, wherein a portion of the semiconductor liner grows on an end of the buried doped semiconductor layer.

8. The method of claim 1, wherein etching the layer stack, the STI structure, and the semiconductor layer to form the trench comprises:
etching into a portion of a substrate layer under the semiconductor layer such that a bottom of the trench is located in the substrate layer; and
wherein performing the epitaxy process to epitaxially grow the semiconductor liner comprises:
performing the epitaxy process to epitaxially grow the semiconductor liner on the substrate layer at the bottom of the trench.

9. A semiconductor device, comprising:
a substrate layer;
a semiconductor layer above the substrate layer
a buried doped semiconductor layer in the semiconductor layer;
one or more transistor structures above the buried doped semiconductor layer;
a deep trench isolation (DTI) structure in the semiconductor layer,
wherein the DTI structure has a closed-loop shape in a top view of the semiconductor device,
wherein the closed-loop shape of the DTI structure laterally surrounds the buried doped semiconductor layer and the one or more transistor structures, and
wherein the DTI structure comprises:
a two-part insert, comprising:
an elongated portion; and
a capping portion above the elongated portion; and
a semiconductor liner between sidewalls of the elongated portion and the semiconductor layer.

10. The semiconductor device of claim 9, wherein the capping portion extends laterally over ends of the semiconductor liner.

11. The semiconductor device of claim 9, further comprising:
a shallow trench isolation (STI) structure in the semiconductor layer,
wherein the DTI structure extends through the STI structure, and
wherein the capping portion of the two-part insert is located in the STI structure.

12. The semiconductor device of claim 11, wherein ends of the semiconductor liner are located above a bottom surface of the STI structure.

13. The semiconductor device of claim 9, wherein the semiconductor liner comprises:
a silicon (Si) buffer layer;
a doped silicon passivation layer on the silicon buffer layer; and
a silicon capping liner on the silicon buffer layer.

14. The semiconductor device of claim 9, wherein a first thickness of the semiconductor liner at a top of the DTI structure is greater than a second thickness (D11) at a bottom of the DTI structure.

15. The semiconductor device of claim 14, wherein a third thickness of the semiconductor liner between a bottom surface of the elongated portion of the two-part insert and the substrate layer is greater than the second thickness.

16. The semiconductor device of claim 9, wherein an angle between a sidewall of the capping portion of the two-part insert, and a bottom surface of the capping portion, is greater than approximately 90 degrees.

17. A method, comprising:
forming a shallow trench isolation (STI) structure in a semiconductor layer of a semiconductor device;
depositing a layer stack above the semiconductor layer and above the STI structure;
etching the layer stack, the STI structure, and the semiconductor layer to form a trench that extends through the STI structure and that laterally surrounds a buried doped semiconductor layer in the semiconductor layer,
wherein a bottom of the trench is lower in the semiconductor layer than the buried doped semiconductor layer;
performing an epitaxy process to epitaxially grow a multi-layer semiconductor liner on sidewalls of the trench,
wherein dielectric material of the STI structure resists growth of the multi-layer semiconductor liner on the STI structure; and
depositing material in an area in the trench between segments of the semiconductor liner to form an insert in the trench,
wherein the segments of the multi-layer semiconductor liner and the insert correspond to an elongated isolation structure in the semiconductor that laterally surrounds the buried doped semiconductor layer,
wherein an elongated portion of the insert under the STI structure has a first lateral width in a direction that is approximately perpendicular to a length of the elongated isolation structure,
wherein a capping portion of the insert in the STI structure has a second lateral width in the direction that is approximately perpendicular to the length of the elongated isolation structure, and
wherein the second lateral width is greater than the first lateral width.

18. The method of claim 17, wherein performing the epitaxy process to epitaxially grow the multi-layer semiconductor liner comprises:
performing the epitaxy process to epitaxially grow a silicon (Si) buffer layer on the sidewalls of the trench, to epitaxially grow a doped silicon passivation layer on the silicon buffer layer, and to epitaxially grow a silicon capping liner on the silicon buffer layer.

19. The method of claim 18, wherein a first thickness of the doped silicon passivation layer is greater than a second thickness of the silicon buffer layer; and
wherein the first thickness of the doped silicon passivation layer is greater than a third thickness of the silicon capping liner.

20. The method of claim 19, wherein the doped silicon passivation layer is doped with at least one of:
carbon(C); or
phosphorous (P).
